(19) United States
(12) Patent Application Publication
(10) Pub. No.: US 2026/0173709 A1
(43) Pub. Date: Jun. 18, 2026

(54) DISPLAY DEVICE

(71) Applicant: LG DISPLAY CO., LTD., SEOUL (KR)

(72) Inventors: Jihyang Yoon, Paju-si (KR); YunHo Kook, Paju-si (KR); Jonghan Park, Paju-si (KR); Seungpyo Hong, Paju-si (KR)

(21) Appl. No.: 19/375,344

(22) Filed: Oct. 31, 2025

(30) Foreign Application Priority Data
Dec. 18, 2024 (KR) 10-2024-0189821

(51) Int. Cl. H10K 59/40; H10K 59/122; H10K 59/124; H10K 59/35; H10K 59/80

(52) U.S. Cl. CPC H10K 59/40; H10K 59/122; H10K 59/124; H10K 59/353; H10K 59/80515

(57) ABSTRACT

A display device includes a touch metal that is included in a touch electrode disposed on an encapsulating layer. The touch metal is perforated with a plurality of pores that penetrate through the touch metal in a direction perpendicular to a substrate, thereby increasing light efficiency by transmitting light output from a light emitting device and addressing a problem of luminance non-uniformity in a sub-emission area.

### CROSS REFERENCE TO RELATED APPLICATION

Pursuant to 35 U.S.C. § 119(a), this application claims the benefit of an earlier filing date and right of priority to Korean Patent Application No. 10-2024-0189821, filed on Dec. 18, 2024, the entire contents of which are hereby incorporated by reference for all purposes as if fully set forth herein.

### TECHNICAL FIELD

The present disclosure generally relates to a display device.

### BACKGROUND

As information society develops, the demand for display devices for displaying images is increasing in various forms, and recently, various display devices such as liquid crystal displays and organic light-emitting display devices are being utilized.

Among display devices, there is a display devices that provides a touch-based input method capable of allowing a user to intuitively and conveniently input information or commands in addition to the input methods such as buttons, keyboards, and mice.

Such a display device may include a plurality of touch electrodes for touch sensing. Since these plurality of touch electrodes are arranged on a light emitting device of the display device, they may prevent light generated from the light emitting devices from being output outside the display panel, which may lower the brightness.

### SUMMARY

Implementations of the present disclosure can provide a display device including a substrate including a display area and a non-display area, a plurality of pixel electrodes arranged on the display area of the substrate, a common electrode arranged on the plurality of pixel electrodes, an encapsulation layer disposed on the common electrode, and a touch electrode disposed on the encapsulation layer and including a touch metal having a plurality of open areas, wherein the touch metal is perforated with a plurality of pores that penetrate through the touch metal in a direction perpendicular to the substrate.

Implementations of the present disclosure can provide a display device including a substrate including a display area, a pixel electrode included in a sub-pixel disposed in the display area, the pixel electrode including a flat surface and an inclined surface outside a periphery of the flat surface, a bank disposed on the pixel electrode and having a hole overlapping with at least a portion of the pixel electrode, and a touch metal disposed on the bank and having a plurality of pores. An emission area of the sub-pixel may include a first emission area overlapping with the flat surface of the pixel electrode, a second emission area surrounding the first emission area and overlapping with at least a portion of the inclined surface of the pixel electrode, and a third emission area outside a periphery of the second emission area and overlapping with at least a part of the plurality of pores.

Implementations of the present disclosure can provide various technical benefits. For example, implementations of the present disclosure can provide a display device capable of increasing the luminance by forming a sub-emission area through a pixel electrode including an inclined surface.

According to implementations of the present disclosure, it is possible to provide a display device capable of increasing luminous efficiency by forming an open area corresponding to an emission area on a touch electrode.

According to implementations of the present disclosure, it is possible to provide a display device capable of increasing light efficiency by forming pores in the touch metal included in the touch electrode and transmitting light output from the light emitting device.

According to implementations of the present disclosure, it is possible to provide a display device capable of solving the problem of uneven luminance in an emission area that may occur due to higher luminance in a non-corner sub-emission area than in a corner sub-emission area by forming the size of a corner pore larger than that of a non-corner pore.

According to implementations of the present disclosure, it is possible to provide a display device capable of implementing the high luminance with low power by forming the pores transmit light in a touch metal.

The effects of the implementations of the present disclosure are not limited to the effects mentioned in this disclosure, and other effects not mentioned will be clearly understood by those skilled in the art from the description of the claims.

### BRIEF DESCRIPTION OF THE DRAWINGS

FIG. 1 illustrates an example of a system configuration diagram of a display device according to implementations of the present disclosure.

FIG. 2 illustrates an example of a display panel according to implementations of the present disclosure.

FIG. 3 illustrates an example of a touch sensor structure of a display device performing mutual capacitance-based touch sensing according to an implementation of the present disclosure.

FIG. 4 illustrates an example of a touch sensor structure of a display device performing self-capacitance-based touch sensing according to implementations of the present disclosure.

FIG. 5 is a cross-sectional view of an example of a display panel according to implementations of the present disclosure.

FIG. 6 is a drawing of an example of a correspondence relationship between a mesh-type touch electrode and a sub-pixel in a display device according to implementations of the present disclosure.

FIG. 7 is an example of a plan view that enlarges an X area of a touch electrode shown in FIG. 6.

FIG. 8 is an example of a plan view that enlarges an A area of a touch electrode shown in FIG. 7.

FIG. 9 is a part of a cross-sectional view of a display panel along the line B-B′ shown in FIG. 8.

FIG. 10 is a drawing of an example of a mesh-type touch electrode including the pores in a display device according to implementations of the present disclosure.

FIG. 11 is an example of a plan view illustrating an enlarged area A of the touch electrode in the case that a touch metal of aa touch electrode in FIG. 7 includes the pores as in FIG. 10.

FIG. 12 is a part of a cross-sectional view of the display panel along the line C-C′ shown in FIG. 11.

FIGS. 13 and 14 are plan views illustrating examples of a shape of the pore arranged in the touch metal.

FIG. 15 is a plan view illustrating an example of an emission area in the plan view corresponding to FIG. 8.

FIG. 16 is a plan view illustrating an example of an emission area in the plan view corresponding to FIG. 11.

### DETAILED DESCRIPTION

Implementations of the present disclosure can provide a display device capable of increasing the luminance by forming a sub-emission area through a pixel electrode including an inclined surface.

Implementations of the present disclosure can provide a display device capable of increasing luminous efficiency by forming an open area corresponding to an emission area on a touch electrode.

Implementations of the present disclosure can provide a display device capable of increasing light efficiency by forming pores in the touch metal included in the touch electrode and transmitting light output from the light emitting device.

Implementations of the present disclosure can provide a display device that implements a corner pore having a larger size than a non-corner pore, which can help address a problem of uneven luminance in an emission area that may occur due to higher luminance in a non-corner sub-emission area than in a corner sub-emission area.

Implementations of the present disclosure can provide a display device capable of implementing the high luminance with low power by forming the pores transmit light in a touch metal.

In the following description of examples or implementations of the present disclosure, reference will be made to the accompanying drawings in which it is shown by way of illustration specific examples or implementations that can be implemented, and in which the same reference numerals and signs can be used to designate the same or like components even when they are shown in different accompanying drawings from one another. Further, in the following description of examples or implementations of the present disclosure, detailed descriptions of well-known functions and components incorporated herein will be omitted when it is determined that the description may make the subject matter in some implementations of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”

Hereinafter, various implementations of the disclosure are described in detail with reference to the accompanying drawings.

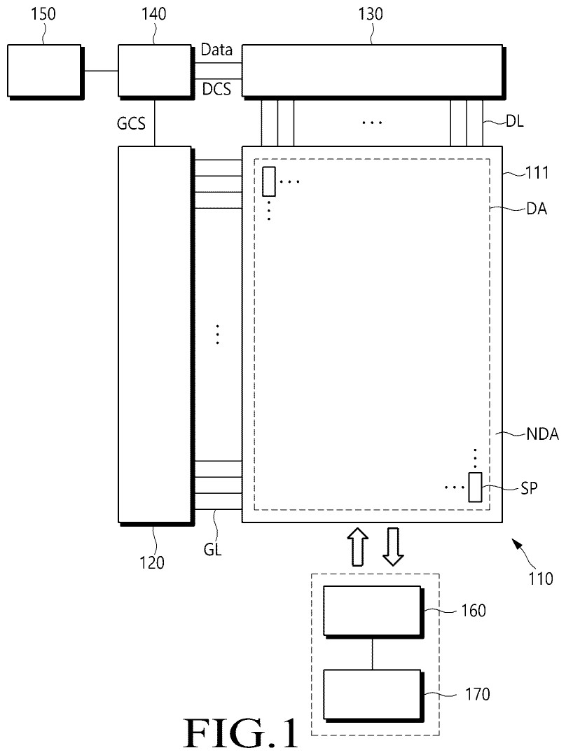

FIG. 1 illustrates an example of a system configuration diagram of a display device 100 according to implementations of the present disclosure.

Referring to FIG. 1, the display device 100 may include a display panel 110 and a display driving circuit as components for displaying an image.

The display driving circuit may be a circuit for driving the display panel 110, and may include a data driving circuit 130, a gate driving circuit 120 and a display controller 140.

The display panel 110 may include a display area DA for displaying an image and a non-display area NDA where an image is not displayed. The non-display area NDA may be an area outside the display area DA, and may also be referred to as a bezel area. All or part of the non-display area NDA may be an area visible from the front of the display device 100, or may be an area which is bent and not visible from the front of the display device 100.

The display panel 110 may include a substrate 111 and a plurality of sub-pixels SP disposed on the substrate 20. Additionally, the display panel 110 may further include various types of signal lines to drive the plurality of sub-pixels SP.

The display device 100 according to implementations of the present disclosure may be a self-luminous display device in which the display panel 110 emits light on its own. However, the display device 100 according to the implementations of the present disclosure is not limited to a self-luminous display device. If the display device 100 according to the implementations of the present disclosure is a self-luminous display device, each of the plurality of sub-pixels SP may include a light emitting device. For example, the display device 100 according to the implementations of the present disclosure may be an organic light-emitting display device in which the light emitting device is implemented as an organic light-emitting diode (OLED). For another example, the display device 100 according to the implementations of the present disclosure may be an inorganic light-emitting display device in which the light emitting device is implemented as an inorganic-based light-emitting diode. For another example, the display device 100 according to the implementations of the present disclosure may be a quantum dot display device in which the light emitting device is implemented as a quantum dot, which is a semiconductor crystal that emits light by itself.

The structure of each of the plurality of sub-pixels SP may vary depending on the type of the display device 10. For example, if the display device 100) is a self-luminous display device in which sub-pixels SP emit light by themselves, each sub-pixel SP may include a light emitting device that emits light by itself, one or more transistors, and one or more capacitors.

For example, various types of signal lines may include a plurality of data lines DL that transmit data signals (also called data voltages or image signals) and a plurality of gate lines GL that transmit gate signals (also called scan signals).

The plurality of data lines DL and the plurality of gate lines GL may cross each other. Each of the plurality of data lines DL may be arranged to extend in a first direction. Each of the plurality of gate lines GL may be arranged to extend in a second direction. Here, the first direction may be a column direction and the second direction may be a row direction. Alternatively, the first direction may be a row direction and the second direction may be a column direction.

The data driving circuit 130 is a circuit for driving a plurality of data lines DL, and may output data signals to the plurality of data lines DL. The gate driving circuit 120 is a circuit for driving a plurality of gate lines GL, and may output gate signals to the plurality of gate lines GL.

The display controller 140 may be a device for controlling the data driving circuit 130 and the gate driving circuit 120 depending on the timing implemented in each frame, and may control the driving timing for the plurality of data lines DL and the driving timing of the plurality of gate lines GL.

The display controller 140 may supply a data driving control signal DCS to the data driving circuit 130 to control the data driving circuit 130, and may supply a gate driving control signal GCS to the gate driving circuit 120 to control the gate driving circuit 120.

The display controller 140 may receive input image data from a host system 150 and supply image data to the data driving circuit 130 based on the input image data.

The data driving circuit 130 may receive image data in digital form from the display controller 140 and convert the received image data into analog data signals to output to a plurality of data lines DL.

The gate driving circuit 120 may receive a first gate voltage corresponding to the turn-on level voltage and a second gate voltage corresponding to the turn-off level voltage along with various gate driving control signals GCS, and may generate gate signals and supply the generated gate signals to the plurality of gate lines GL.

For example, the data driving circuit 130 may be connected to the display panel 110 in a tape automated bonding (TAB) manner, connected to a bonding pad of the display panel 110 in a chip-on-glass (COG) or chip-on-panel (COP) manner, or implemented in a chip-on-film (COF) manner and connected to the display panel 110.

The gate driving circuit 120 may be connected to the display panel 110 by a tape automated bonding (TAB) method, connected to a bonding pad of the display panel 110 by a chip-on-glass (COG) or chip-on-panel (COP) method, or connected to the display panel 110 by a chip-on-film (COF) method. Alternatively, the gate driving circuit 120 may be formed in a non-display area NDA of the display panel 110 by a gate-in-panel (GIP) type. The gate driving circuit 120 may be disposed on or connected to the substrate. That is, the gate driving circuit 120 may be disposed in the non-display area NDA of the substrate if it is a GIP type. The gate driving circuit 120 may be connected to the substrate if it is a chip-on-glass (COG) type, a chip-on-film (COF) type, etc.

In some implementations, at least one of the data driving circuit 130 and the gate driving circuit 120 may be disposed in the display area DA of the display panel 110. For example, at least one of the data driving circuit 130 and the gate driving circuit 120 may be disposed so as not to overlap with the sub-pixels SP, or may be disposed so as to partially or completely overlap with the sub-pixels SP.

The data driving circuit 130 may be connected to one side (e.g., the upper side or the lower side) of the display panel 110. Depending on the driving method, panel design method, etc., the data driving circuit 130 may be connected to both sides (e.g., the upper side and the lower side) of the display panel 110, or may be connected to two or more sides among the four sides of the display panel 110.

The gate driving circuit 120 may be connected to one side (e.g., left or right) of the display panel 110. Depending on the driving method, panel design method, etc., the gate driving circuit 120 may be connected to both sides (e.g., left and right) of the display panel 110, or may be connected to two or more of the four sides of the display panel 110.

The display controller 140 may be implemented as a separate component from the data driving circuit 130, or may be implemented as an integrated circuit by being integrated with the data driving circuit 130.

The display controller 140 may be a timing controller used in display technology, or may be a control device capable of performing other control functions including a timing controller, or may be a control device other than the timing controller or a circuit within the control device. The display controller 140 may be implemented as various circuits or electronic components such as an integrated-circuit (IC), a field programmable gate array (FPGA), an application specific integrated-circuit (ASIC), or a processor.

The display controller 140 may be mounted on a printed circuit board or a flexible printed circuit, and may be electrically connected to the data driving circuit 130 and the gate driving circuit 120 through the printed circuit board or the flexible printed circuit.

The display controller 140 may transmit and receive signals with the data driving circuit 130 according to one or more predefined interfaces. Here, for example, the interface may include an LVDS (Low Voltage Differential Signaling) interface, an EPI interface, an SP (Serial Peripheral) interface, etc.

The display device 100 according to the implementations of the present disclosure may include a touch sensor and a touch sensing circuit that senses the touch sensor to detect an occurrence of a touch by a touch object such as a finger or a pen or detects a touch position in order to provide a touch sensing function in addition to an image display function.

The touch sensing circuit may include a touch driving circuit 160 that drives and senses the touch sensor to generate and output touch sensing data, and a touch controller 170 that detects a touch occurrence or a touch position using the touch sensing data.

The touch sensor may include a plurality of touch electrodes. The touch sensor may further include a plurality of touch lines for electrically connecting a plurality of touch electrodes and a touch driving circuit 160.

The touch sensor may be present in the form of a touch panel on the outside of the display panel 110, or may be present inside the display panel 110. If the touch sensor is present in the form of a touch panel on the outside of the display panel 110, the touch sensor may be referred to as an external type. If the touch sensor is an external type, the touch panel and the display panel 110 may be manufactured separately and combined during the assembly process. The external type touch panel may include a substrate for a touch panel and a plurality of touch electrodes on the substrate for the touch panel.

If the touch sensor is present inside the display panel 110, the touch sensor may be formed on the substrate 111 together with signal lines and electrodes related to display driving during the manufacturing process of the display panel 110.

The touch driving circuit 160 may supply a touch driving signal to at least one of the plurality of touch electrodes and generate touch sensing data by sensing at least one of the plurality of touch electrodes.

The touch sensing circuit may perform touch sensing in a self-capacitance sensing method or a mutual-capacitance sensing method.

If the touch sensing circuit performs touch sensing in a self-capacitance sensing method, the touch sensing circuit may perform touch sensing based on the capacitance between each touch electrode and a touch object (e.g., a finger, a pen, etc.). According to the self-capacitance sensing method, each of the plurality of touch electrodes may act as a driving touch electrode and also act as a sensing touch electrode. The touch driving circuit 160 may drive all or part of the plurality of touch electrodes and sense all or part of the plurality of touch electrodes.

If the touch sensing circuit performs touch sensing in a mutual-capacitance sensing method, the touch sensing circuit may perform touch sensing based on the capacitance between the touch electrodes. According to the mutual-capacitance sensing method, a plurality of touch electrodes may be divided into driving touch electrodes and sensing touch electrodes. The touch driving circuit 160 may drive the driving touch electrodes and sense the sensing touch electrodes.

The touch driving circuit 160 and the touch controller 170 included in the touch sensing circuit may be implemented as separate devices or as one device. In addition, the touch driving circuit 160 and the data driving circuit 130 may be implemented as separate devices or as one device.

The display device 100 may further include a power supply circuit that supplies various types of power to the display driving circuit and/or the touch sensing circuit.

The display device 100 according to the implementations of the present disclosure may be a mobile terminal such as a smart phone or tablet, or a monitor or television (TV) of various sizes, and may be a display of various types and sizes capable of displaying information or images, without being limited thereto.

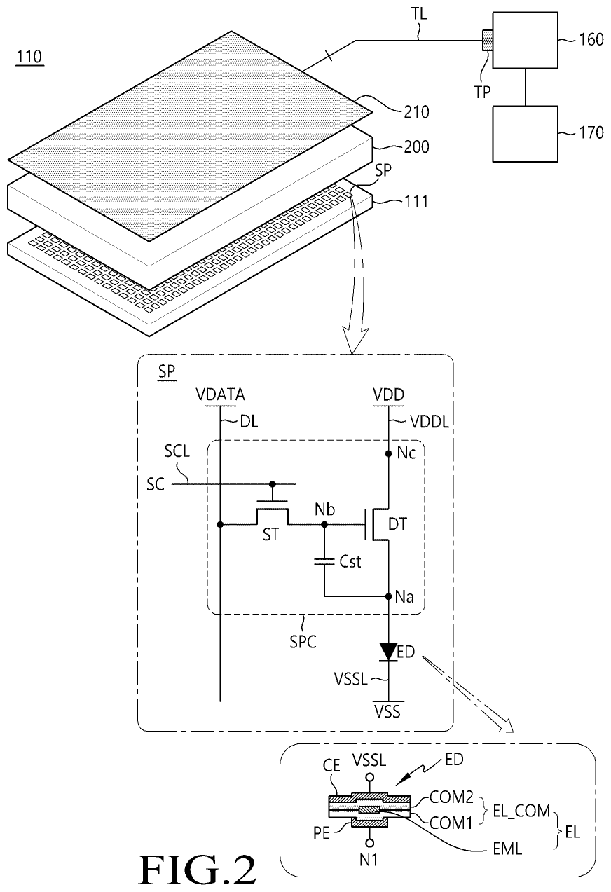

FIG. 2 illustrates an example of a display panel 110 according to implementations of the present disclosure.

Referring to FIG. 2, the display panel 110 according to the implementations of the present disclosure may include a substrate 111 on which a plurality of sub-pixels SP are arranged, and an encapsulation layer 200 on the substrate 111. The encapsulation layer 200 may also be referred to as an encapsulation substrate or an encapsulation section.

Referring to FIG. 2, if the display device 100 according to the implementations of the present disclosure is a self-luminous display device, each of the plurality of sub-pixels SP arranged on the substrate 111 may include a light emitting device ED and a sub-pixel circuit SPC for driving the light emitting device ED.

Referring to FIG. 2, the sub-pixel circuit SPC may include a plurality of transistors for driving the light emitting device ED and at least one capacitor, but the implementations of the present disclosure are not limited thereto. In the present disclosure, the sub-pixel circuit SPC may drive the light emitting device ED by supplying a driving current to the light emitting device ED at a predetermined timing. The light emitting device ED may be driven by the driving current to emit light.

The plurality of transistors may include a driving transistor DT for driving the light emitting device ED and a scan transistor ST that is turned on or off according to a scan signal SC.

The driving transistor DT may supply a driving current to the light emitting device ED. The scan transistor ST may be configured to control an electrical state of a corresponding node within the sub-pixel circuit SPC or to control a state or operation of the driving transistor DT. At least one capacitor may include a storage capacitor Cst for maintaining a constant voltage during a frame.

In order to drive the sub-pixel SP, a data signal VDATA, which is an image signal, and a scan signal SC, which is a type of gate signal, may be applied to the sub-pixel SP. In addition, in order to drive the sub-pixel SP, a common driving signal including a driving voltage VDD and a base voltage VSS may be applied to the sub-pixel SP.

The light emitting device ED may include a pixel electrode PE, an intermediate layer EL, and a common electrode CE. An intermediate layer EL may be disposed between the pixel electrode PE and the common electrode CE.

For example, the pixel electrode PE may be an electrode disposed in each sub-pixel SP, and the common electrode CE may be an electrode commonly disposed in a plurality of sub-pixels SP. For example, the pixel electrode PE may be the anode and the common electrode CE may be the cathode. For another example, the pixel electrode PE may be the cathode and the common electrode CE may be the anode. Hereinafter, for convenience of explanation, implementations are described in which the pixel electrode PE is the anode and the common electrode CE is the cathode.

In some implementations, the light emitting device ED is an organic light emitting device, in which case the intermediate layer EL may include an emission layer EML, a first common intermediate layer COM1 between the pixel electrode PE and the emission layer EML, and a second common intermediate layer COM2 between the emission layer EML and the common electrode CE. In some implementations, the first common intermediate layer COM1 and the second common intermediate layer COM2 may be combined and referred to as a common intermediate layer EL_COM.

The emission layer EML may be disposed separately for each sub-pixel SP, or may be disposed commonly across a plurality of sub-pixels SP. The common intermediate layer EL_COM may be commonly arranged across a plurality of sub-pixels SP, but the implementations of the present disclosure are not limited thereto.

For example, the emission layer EML may be disposed separately in each emission area EA, or may be commonly disposed across a plurality of emission areas EA. The common intermediate layer EL_COM may be commonly disposed across a plurality of emission areas EA and non-emission areas, but the implementations of the present disclosure are not limited thereto.

For example, the first common intermediate layer COM1 may include a hole injection layer HIL, an electron blocking layer EBL, and a hole transfer layer HTL, but the implementations of the present disclosure are not limited thereto. The second common intermediate layer COM2 may include an electron transfer layer ETL, a hole blocking layer HBL, and an electron injection layer EIL, but the implementations of the present disclosure are not limited thereto.

The hole injection layer HIL may inject holes from the pixel electrode PE to the hole transport layer HTL, the hole transport layer HTL may transport holes to the emission layer EML, the electron injection layer EIL may inject electrons from the common electrode CE to the electron transport layer ETL, and the electron transport layer ETL may transport electrons to the emission layer EML.

For example, the common electrode CE may be electrically connected to a base voltage line VSSL. A base voltage VSS, which is a type of common voltage, may be applied to the common electrode CE through the base voltage line VSSL. The pixel electrode PE may be electrically connected directly or indirectly (via another transistor) to the first node Na of the driving transistor DT of each sub-pixel SP. In the present disclosure, the base voltage VSS may also be referred to as a first common voltage, a low-potential power supply voltage, or a low-potential voltage, and the base voltage line VSSL may also be referred to as a first common voltage line, a low-potential power supply voltage line, or a low-potential voltage line.

Each light emitting device ED may include a portion overlapping with a pixel electrode PE, an emission layer EML in an intermediate layer EL, and a common electrode CE. An emission area EA may be formed by each light emitting device ED. For example, the emission area EA of each light emitting device ED may include a portion overlapping with a pixel electrode PE, an emission layer EML in an intermediate layer EL, and a common electrode CE.

For example, the light emitting device ED may be an organic light emitting diode (OLED), an inorganic-based light emitting diode (LED), a quantum dot light emitting device, a micro LED, or a mini LED, but the implementations of the present disclosure are not limited thereto. For example, if the light emitting device ED is an organic light emitting diode (OLED), the intermediate layer EL in the light emitting device ED may include an intermediate layer EL containing an organic material.

The driving transistor DT may be a driving transistor for supplying a driving current to the light emitting device ED. The driving transistor DT may be connected between a driving voltage line VDDL and the light emitting device ED.

The driving transistor DT may include a first node Na, a second node Nb, and a third node Nc. The first node Na may be electrically connected to a light emitting device ED, a second node Nb may be applied with a data signal VDATA, and a third node Nc may be applied with a driving voltage VDD, which is another type of common voltage, from a driving voltage line VDDL. The driving transistor DT may be connected on the first node Na and the third node Nc. In the present disclosure, the driving voltage VDD may also be described as a second common voltage, a high-potential power supply voltage, or a high-potential voltage, and the driving voltage line VDDL may also be described as a second common voltage line, a low-potential power supply voltage line, or a low-potential voltage line.

In the driving transistor DT, the second node Nb may be a gate node, the first node Na may be a source node or a drain node, and the third node Nc may be a drain node or a source node. Hereinafter, for convenience of explanation, in the driving transistor DT, the second node Nb may be a gate node, the first node Na may be a source node, and the third node Nc may be a drain node, but the implementations of the present disclosure are not limited thereto.

A scan transistor ST included in the sub-pixel circuit SPC illustrated in FIG. 2 may be a switching transistor for transmitting a data signal VDATA, which is an image signal, to the second node Nb, which is a gate node of the driving transistor DT.

The scan transistor ST may be turned on and off by a scan signal SC, which is a type of gate signal applied through a scan line SCL, which is a type of gate line GL, so as to control the electrical connection between the second node Nb of the driving transistor DT and the data line DL. The drain electrode or the source electrode of the scan transistor ST may be electrically connected to the data line DL, the source electrode or the drain electrode of the scan transistor ST may be electrically connected to the second node Nb of the driving transistor DT, and the gate electrode of the scan transistor ST may be electrically connected to the scan line SCL.

The storage capacitor Cst may be electrically connected between the first node Na and the second node Nb of the driving transistor DT. The storage capacitor Cst may include at least one capacitor electrode electrically connected to the first node Na of the driving transistor DT or corresponding to the first node Na of the driving transistor DT, and at least one capacitor electrode electrically connected to the second node Nb of the driving transistor DT or corresponding to the second node Nb of the driving transistor DT.

The storage capacitor Cst may be an external capacitor intentionally designed outside the driving transistor DT, rather than a parasitic capacitor (e.g., Cgs, Cgd) that may be an internal capacitor between the first node Na and the second node Nb of the driving transistor DT, but implementations of the present disclosure are not limited thereto.

Each of the driving transistor DT and the scan transistor ST may be an n-type transistor or a p-type transistor, but the implementations of the present disclosure are not limited thereto. For example, one of the driving transistor DT and the scan transistor ST may be one of an n-type transistor and a p-type transistor.

The display panel 110 may have a top emission structure or a bottom emission structure. If the display panel 110 has a top emission structure, at least a portion of the sub-pixel circuit SPC may overlap with at least a portion of the light emitting device ED in a vertical direction. Accordingly, the size of the emission area EA may be increased and the aperture ratio may be increased. If the display panel 110 has a bottom emission structure, the sub-pixel circuit SPC may not overlap with the light emitting device ED in the vertical direction.

The sub-pixel circuit SPC may have a 2T(Transistor)1C(Capacitor) structure including two transistors (e.g., DT and ST) and one capacitor Cst as illustrated in FIG. 2, and may further include one or more transistors or one or more capacitors, depending on the case.

As an example, the sub-pixel circuit SPC may have a 3T1C structure including three transistors and one capacitor. As another example, the sub-pixel circuit SPC may have an 8T1C structure including eight transistors and one capacitor. As another example, the sub-pixel circuit SPC may have a 6T2C structure including six transistors and two capacitors. As another example, the sub-pixel circuit

SPC may have a 7T1C structure including seven transistors and one capacitor, however, the implementations of the present disclosure are not limited thereto.

Depending on the structure of the sub-pixel circuit SPC, the type and number of gate signal supplied to the sub-pixel SP and the number of the gate lines may vary. In addition, depending on the structure of the sub-pixel circuit SPC, the type and number of common driving signals supplied to the sub-pixel SP may vary.

Since the circuit elements (e.g., light emitting devices ED implemented as organic light-emitting diodes (OLED) including organic materials) in each sub-pixel SP are vulnerable to external moisture or oxygen, an encapsulation layer 200 may be provided on the display panel 110. The encapsulation layer 200 may prevent external moisture or oxygen from penetrating into the circuit elements (e.g., light emitting devices ED). The encapsulation layer 200 may be configured in various forms so that the light emitting devices ED do not come into contact with moisture or oxygen. For example, the encapsulation layer 200 may be configured with two or more layers in which organic films and inorganic films are alternately laminated, but the implementations of the present disclosure are not limited thereto.

Referring to FIG. 2, the display device 100 according to the implementations of the present disclosure may include a touch sensor layer 210 with a touch sensor, and a touch sensing circuit that senses the touch sensor formed in the touch sensor layer 210 to determine the presence or absence of a touch or a touch coordinate in order to provide a touch sensing function. Here, the touch sensor layer 210 may also be referred to as a touch unit or a touch sensing unit.

For example, the touch sensing circuit may include a touch driving circuit 160 configured to drive and sense the touch sensor formed in the touch sensor layer 210 to generate and output touch sensing data, and a touch controller 170 configured to determine the presence or absence of a touch or a touch coordinate using the touch sensing data provided by the touch driving circuit 160.

The touch sensor layer 210 may be a layer in which a touch sensor is formed, and the touch sensor may be configured with a plurality of touch electrodes.

For example, the touch sensor layer 210 may be disposed outside the display panel 110, and may be configured as a separate touch panel from the display panel 110. In this case, the touch panel and the display panel 110 may be manufactured separately and combined during the assembly process.

For another example, the touch sensor layer 210 may be built into the display panel 110. If the touch sensor layer 210 is included inside the display panel 110, the touch sensor layer 210 may be formed on the substrate 111 together with signal lines and electrodes related to display driving during the manufacturing process of the display panel 110. For example, the touch sensor layer 210 may be disposed on the encapsulation layer 200. Hereinafter, for convenience of explanation, implementations are described in which the touch sensor layer 210 is built into the display panel 110.

If the touch sensor layer 210 is embedded in the display panel 110, the display panel 110 may further include, in addition to a plurality of touch electrodes corresponding to the touch sensor, a plurality of touch pads TP to which the touch driving circuit 160 is electrically connected, and a plurality of touch routing lines TL electrically connecting the plurality of touch electrodes and the plurality of touch pads TP. Here, the plurality of touch routing lines TL may also be referred to as a plurality of touch lines. In addition, the plurality of touch routing lines TL may correspond to a plurality of touch channels.

The touch driving circuit 160 may supply a touch driving signal to at least one of the plurality of touch electrodes, and sense at least one of the plurality of touch electrodes to generate touch sensing data.

The touch sensing circuit may perform touch sensing operation using a self-capacitance sensing method or a mutual-capacitance sensing method.

If the touch sensing circuit performs touch sensing operation in a self-capacitance sensing method, the touch sensing circuit may perform touch sensing based on the capacitance between each touch electrode and a touch object (e.g., a finger, a pen, etc.). According to the self-capacitance sensing method, each of the plurality of touch electrodes may function as a driving touch electrode and also act as a sensing touch electrode. The touch driving circuit may drive all or part of the plurality of touch electrodes and sense all or part of the plurality of touch electrodes.

If the touch sensing circuit performs touch sensing in a mutual-capacitance sensing method, the touch sensing circuit may perform touch sensing based on the capacitance between two adjacent touch electrodes. According to the mutual-capacitance sensing method, the plurality of touch electrodes may include driving touch electrodes and sensing touch electrodes. The touch driving circuit may drive the driving touch electrodes and sense the sensing touch electrodes. The touch routing lines connected to the driving touch electrodes may be referred to as driving touch routing lines, and the touch routing lines connected to the sensing touch electrodes may be referred to as sensing touch routing lines.

The touch driving circuit 160 and the touch controller 170 may be implemented as separate devices or as one device. In addition, the touch driving circuit 160 and the data driving circuit 130 may be implemented as separate devices or as one device.

The display device 100 may further include a power supply circuit that supplies various powers to the display driving circuit and/or the touch sensing circuit. The power supply circuit may supply various voltages and power voltages related to display driving to the display driving circuit or the display panel 110.

The display device 100 according to some implementations of the present disclosure may sense a touch based on the capacitance formed on the touch electrodes.

The display device 100 according to the implementations of the present disclosure may sense a touch using a mutual-capacitance-based touch sensing method, and can also sense a touch using a self-capacitance-based touch sensing method.

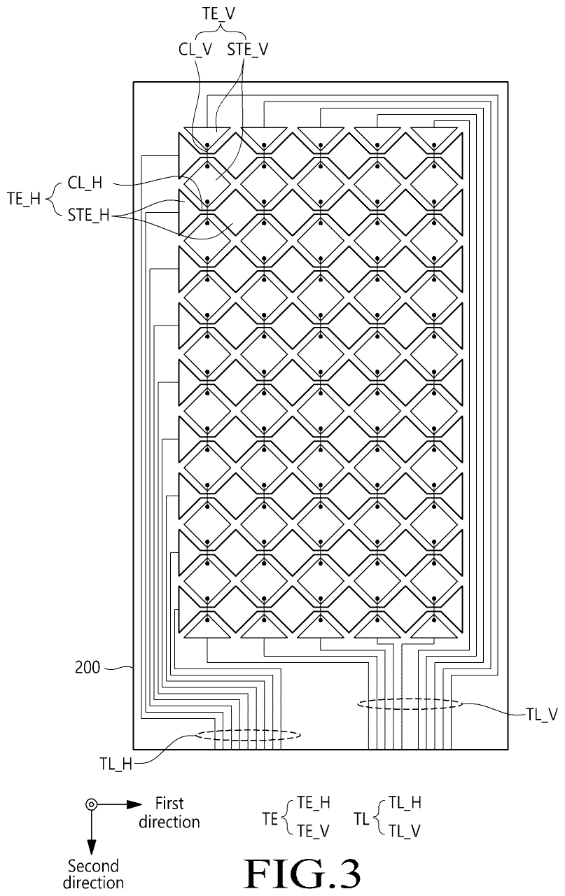

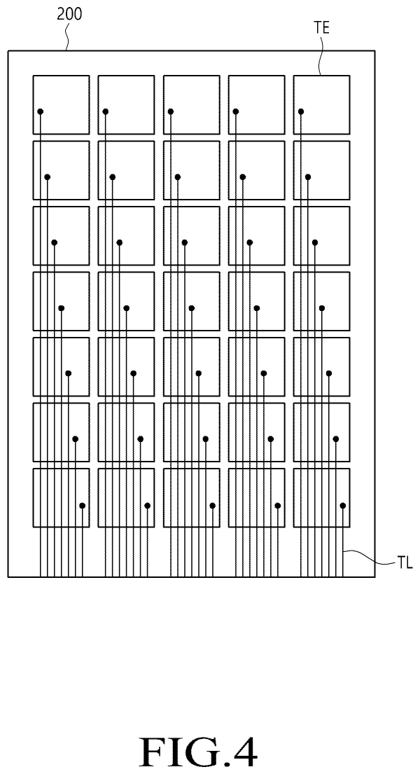

FIG. 3 illustrates an example of a touch electrode TE if the display device 100 senses a touch using a mutual-capacitance-based touch sensing method, and FIG. 4 is an example diagram of a touch electrode TE in the case that the display device 100 according to the implementations of the present disclosure senses a touch using a self-capacitance-based touch sensing method.

FIG. 3 illustrates a touch sensor structure of a display device 100 that performs mutual capacitance-based touch sensing according to an implementation of the present disclosure.

Referring to FIG. 3, the touch sensor according to the implementations of the present disclosure may include a plurality of touch electrodes TE. The plurality of touch electrodes TE may include a plurality of horizontal touch electrodes TE_H and a plurality of vertical touch electrodes TE_V.

The plurality of touch electrodes TE may be arranged in the display area DA and may be arranged on the encapsulation layer 200.

Each of the plurality of horizontal touch electrodes TE_H may include two or more horizontal sub-touch electrodes STE_H arranged in the same row (or column) and one or more horizontal bridge electrodes CL_H electrically connecting the horizontal sub-touch electrodes. For example, as in the example of FIG. 3, two or more horizontal sub-touch electrodes STE_H and one or more horizontal bridge electrodes CL_H constituting one horizontal touch electrode TE_H may be an integrated touch metal (e.g., a second touch metal). As another example, as in the example of FIG. 3, two or more horizontal sub-touch electrodes STE_H may be disposed within a second touch metal layer, and one or more horizontal bridge electrodes CL_H may be disposed within a first touch metal layer.

Each of the plurality of vertical touch electrodes TE_V may include two or more vertical sub-touch electrodes STE_V arranged in the same column (or row) and one or more vertical bridge electrodes CL_V electrically connecting the vertical sub-touch electrodes. For example, two or more vertical sub-touch electrodes STE_V and one or more vertical bridge electrodes CL_V constituting one vertical touch electrode TE_V may be an integrated touch metal (e.g., a second touch metal). As another example, as in the example of FIG. 3, two or more vertical sub-touch electrodes STE_V may be arranged in a second touch metal layer, and one or more vertical bridge electrodes CL_V may be arranged in a first touch metal layer.

In an area where the horizontal touch electrode TE_H and the vertical touch electrode TE_V intersect (e.g., a touch electrode intersection area), the horizontal bridge electrode CL_H and the vertical bridge electrode CL_V may also intersect.

In the touch electrode intersection area, if the horizontal bridge electrode CL_H and the vertical bridge electrode CL_V intersect, the horizontal bridge electrode CL_H and the vertical bridge electrode CL_V are required to be located in different layers.

Therefore, in order for the plurality of horizontal touch electrodes TE_H and the plurality of vertical touch electrodes TE_V to be arranged to intersect, the plurality of horizontal sub-touch electrodes STE_H, the plurality of horizontal bridge electrodes CL_H, the plurality of vertical sub-touch electrodes STE_V, the plurality of vertical touch electrodes TE_V, and the plurality of vertical bridge electrodes CL_V may be located in two or more layers.

Referring to FIG. 3, the touch sensor structure according to the implementations of the present disclosure may further include a plurality of touch routing lines TL. The plurality of touch routing lines TL may include a plurality of horizontal touch routing lines TL_H and a plurality of vertical touch routing lines TL_V.

The plurality of touch routing lines TL may be arranged in a non-display area NDA. At least a portion (e.g., a portion connected to a touch electrode) of the plurality of touch routing lines TL may be located in a display area DA.

The touch sensor structure according to implementations of the present disclosure may further include a plurality of touch pads TP.

At least one of two horizontal sub-touch electrodes STE_H arranged at the outermost sides of one horizontal touch electrode TE_H may be electrically connected to the touch pad TP through the horizontal touch routing line TL_H.

At least one of two vertical sub-touch electrodes STE_V arranged at the outermost sides of one vertical touch electrode TE_V may be electrically connected to the touch pad TP through the vertical touch routing line TL_V.

Meanwhile, as illustrated in FIG. 3, a plurality of horizontal touch electrodes TE_H and a plurality of vertical touch electrodes TE_V may be disposed on an encapsulation layer 200. A plurality of horizontal sub-touch electrodes STE_H and a plurality of horizontal bridge electrodes CL_H constituting a plurality of horizontal touch electrodes TE_H may be disposed on an encapsulation layer 200. A plurality of vertical sub-touch electrodes STE_V and a plurality of vertical bridge electrodes CL_V constituting a plurality of vertical touch electrodes TE_V may be disposed on an encapsulation layer 200.

FIG. 4 illustrates an example of a touch sensor structure of a display device 100 performing self-capacitance-based touch sensing according to implementations of the present disclosure.

Referring to FIG. 4, in the case of a self-capacitance-based touch sensing method, each touch electrode TE placed on the encapsulation layer 200 may have both the role of a driving touch electrode (for driving signal application) and the role of a sensing touch electrode (for sensing signal detection).

For example, a driving signal may be applied to each touch electrode TE, and a sensing signal may be received through the touch electrode TE to which the driving signal is applied. Therefore, in some implementations of the self-capacitance-based touch sensing method, there is no separate distinction between the driving electrode and the sensing electrode.

In the case of the self-capacitance-based touch sensing method, the touch sensing circuit may apply a driving signal to one or more touch electrodes TE, receive a sensing signal from the touch electrodes TE to which the driving signal is applied, and detect the presence or absence of a touch and/or the touch coordinates based on the change in capacitance between a pointer such as a finger or pen and the touch electrode TE based on the received sensing signal. Referring to FIG. 4, each of the plurality of touch electrodes TE may be electrically connected to the touch driving circuit 160 through one or more touch lines TL for transmitting the driving signal and the sensing signal.

In this way, the touch display device according to the implementations of the present disclosure may sense a touch using a mutual-capacitance-based touch sensing method or may sense a touch using a self-capacitance-based touch sensing method.

In the touch display device according to some implementations of the present disclosure, the touch sensor layer 210 may be a built-in type that is manufactured together with the display panel 110 and exists inside the display panel 110. That is, the display panel 110 according to some implementations of the present disclosure may have the touch sensor layer 210 of a built-in type.

In addition, in some implementations of the present disclosure, the touch electrodes TE and the touch lines TL are electrodes and signal wires that exist inside the display panel 110.

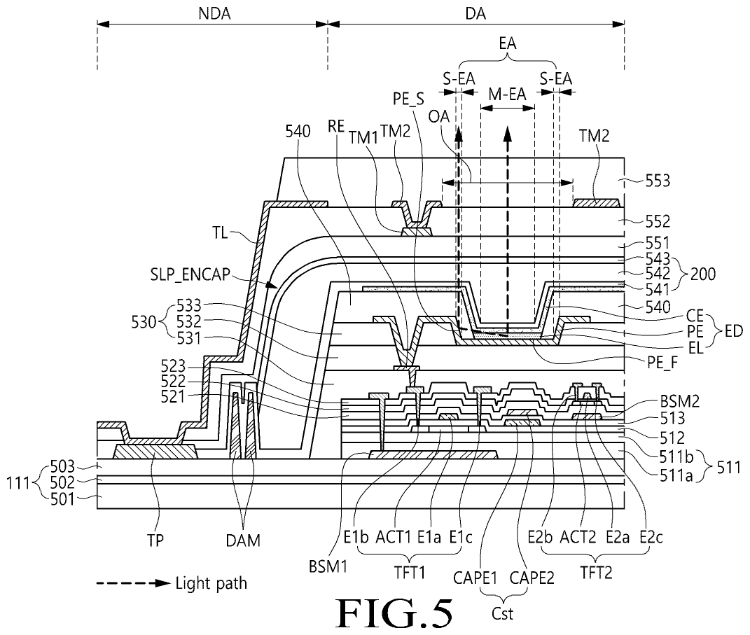

FIG. 5 is a cross-sectional view of an example of the display panel 110 according to the implementations of the present disclosure.

Referring to FIG. 5, the display panel 110 according to the implementations of the present disclosure may include a substrate 111, a transistor section, a light emitting device section, and an encapsulation section, but the implementations of the present disclosure are not limited thereto.

The substrate 111 may be a single layer or a multilayer. If the substrate 111 is a multilayer, the substrate 111 may include a first substrate 501, an intermediate substrate layer 502, and a second substrate 503. The intermediate substrate layer 502 may be located between the first substrate 501 and the second substrate 503. For example, each of the first substrate 501 and the second substrate 503 may be a polyimide (PI) layer, but implementations of the present disclosure are not limited thereto. The intermediate substrate layer 502 may be an inorganic insulating layer, but implementations of the present disclosure are not limited thereto. The intermediate substrate layer 502 can block the charge from affecting the transistors placed on the second substrate 503 through the second substrate 503, which is a polyimide layer, when the charge is charged on the first substrate 501, which is a polyimide layer.

In addition, the intermediate substrate layer 502 can block moisture components from penetrating upward through the first substrate 501. For example, the intermediate substrate layer 502 may be formed of a single layer of silicon nitride (SiNx) or silicon oxide (SiOx), or a multilayer thereof, and may also be formed of a double layer of silicon dioxide (SiO2) and silicon nitride (SiNx), but is not limited thereto.

The transistor section may include a plurality of insulating layers on the substrate 111, thin film transistors TFT1 and TFT2, a storage capacitor Cst, and various electrodes or signal lines. The plurality of insulating layers can include first buffer layer 511, first gate insulating layer 512, first interlayer insulating layer 513, second buffer layer 521, second gate insulating layer 522, and second interlayer insulating layer 523.

The thin film transistors included in the transistor section may include a first thin film transistor TFT1 and a second thin film transistor TFT2.

The first thin film transistor TFT1 may include a first active layer ACT1, a first electrode E1a, a second electrode E1b, and a third electrode E1c.

The first electrode E1a may be a gate electrode, the second electrode E1b may be a source electrode or a drain electrode, and the third electrode E1c may be a drain electrode or a source electrode. Hereinafter, for convenience of explanation, the first electrode E1a may be a first gate electrode E1a, the second electrode E1b may be a first source electrode E1b, and the third electrode E1c may be a first drain electrode E1c. However, the implementations of the present disclosure are not limited thereto.

The first active layer ACT1 may include a first semiconductor material. For example, the first semiconductor material may include an oxide semiconductor, amorphous silicon, polysilicon, or low-temperature polysilicon (LTPS), but the implementations of the present disclosure are not limited thereto. The first thin film transistor TFT1 may be implemented as a p-channel transistor or an n-channel transistor, but the implementations of the present disclosure are not limited thereto.

The second thin film transistor TFT2 may include a second active layer ACT2, a fourth electrode E2a, a fifth electrode E2b, and a sixth electrode E2c.

The fourth electrode E2a may be a gate electrode, the fifth electrode E2b may be a source electrode or a drain electrode, and the sixth electrode E2c may be a drain electrode or a source electrode. Hereinafter, for convenience of explanation, the fourth electrode E2a may be a second gate electrode E2a, the fifth electrode E2b may be a second source electrode E2b, and the sixth electrode E2c may be a second drain electrode E2c. However, the implementations of the present disclosure are not limited thereto.

The second active layer ACT2 may include a second semiconductor material. For example, the second semiconductor material may include an oxide semiconductor, amorphous silicon, polysilicon, or low-temperature polysilicon (LTPS), but the implementations of the present disclosure are not limited thereto. The second thin film transistor TFT2 may be implemented as a p-channel transistor or an n-channel transistor, but the implementations of the present disclosure are not limited thereto.

The types of semiconductor materials of each of the first active layer ACT1 of the first thin film transistor TFT1 and the second active layer ACT2 of the second thin film transistor TFT2 may be as follows.

For example, the first active layer ACT1 of the first thin film transistor TFT1 and the second active layer ACT2 of the second thin film transistor TFT2 may include an oxide semiconductor material. For another example, the first active layer ACT1 of the first thin film transistor TFT1 and the second active layer ACT2 of the second thin film transistor TFT2 may include a low-temperature polysilicon semiconductor material. For another example, the first active layer ACT1 of the first thin film transistor TFT1 may include a low-temperature polysilicon semiconductor material, and the second active layer ACT2 of the second thin film transistor TFT2 may include an oxide semiconductor material. As another example, the first active layer ACT1 of the first thin film transistor TFT1 may include an oxide semiconductor material, and the second active layer ACT2 of the second thin film transistor TFT2 may include a low-temperature polysilicon semiconductor material.

The transistor within the display area DA may be utilized as follows.

As an example, all the transistors within each sub-pixel SP may be implemented as the first thin film transistor TFT1. As another example, all the transistors within each sub-pixel SP may be implemented as the second thin film transistor TFT2. As another example, some of all the transistors within each sub-pixel SP may be implemented as the first thin film transistor TFT1, and some of the remaining transistors may be implemented as the second thin film transistor TFT2. That is, each sub-pixel SP may include at least one first thin film transistor TFT1 and at least one second thin film transistor TFT2.

If some of all the transistors in each sub-pixel SP are implemented as the first thin film transistor TFT1 and the remaining some are implemented as the second thin film transistor TFT2, the following examples may be possible.

As an example, in each sub-pixel SP, the driving transistor DT may be implemented as the first thin film transistor TFT1, and other transistors (e.g., a scan transistor ST, and an emission control transistor) other than the driving transistor DT may be implemented as a second thin film transistor TFT2.

As another example, in each sub-pixel SP, the driving transistor DT may be implemented as the second thin film transistor TFT2, and other transistors (e.g., a scan transistor ST, and an emission control transistor) other than the driving transistor DT may be implemented as the first thin film transistor TFT1.

In FIG. 5, depending on the configuration of the sub-pixel circuit SPC, the first thin film transistor TFT1 connected to the pixel electrode PE of the light emitting device ED may be a driving transistor DT or a transistor different from the driving transistor DT. For example, in FIG. 5, the first thin film transistor TFT1 connected to the pixel electrode PE of the light emitting device ED may be an emission control transistor connected between the driving transistor DT and the light emitting device ED.

The use of the transistors in the non-display area NDA may be as follows.

As an example, the active layers of the transistors included in the gate driving circuit 120 of the gate-in-panel (GIP) type may be composed of an oxide semiconductor material. As another example, the active layers of the transistors included in the gate driving circuit 120 of the gate-in-panel (GIP) type may be composed of a low-temperature polysilicon semiconductor material. As another example, among the transistors included in the gate driving circuit 120 of the gate-in-panel (GIP) type, some active layers may be composed of a low-temperature polysilicon semiconductor material, and other active layers may be composed of an oxide semiconductor material.

The second active layer ACT2 of the second thin film transistor TFT2 may be located higher from the substrate 111 than the first active layer ACT1 of the first thin film transistor TFT1.

A first buffer layer 511 may be disposed under the first active layer ACT1 of the first thin film transistor TFT1, and a second buffer layer 521 may be disposed under the second active layer ACT2 of the second thin film transistor TFT2. For example, the first active layer ACT1 of the first thin film transistor TFT1 may be positioned on the first buffer layer 511, and the second active layer ACT2 of the second thin film transistor TFT2 may be positioned on the second buffer layer 521. The second buffer layer 521 may be positioned higher than the first buffer layer 511.

The storage capacitor Cst may be disposed within various metal layers within the display panel 110, for example, the storage capacitor Cst may include a first capacitor electrode CAPE1 and a second capacitor CAPE2.

The light emitting device section may include a plurality of light emitting devices ED disposed on the planarization layer 530. Each of the plurality of light emitting devices ED may include a pixel electrode PE, an intermediate layer EL, and a common electrode CE.

The encapsulation section may include an encapsulation layer 200 on the plurality of light emitting devices ED. The encapsulation layer 200 may be a single layer or a multilayer, but the implementations of the present disclosure are not limited thereto. In addition to the encapsulation layer 200, the encapsulation section may further include at least one dam DAM to prevent a material constituting the encapsulation layer 200 from overflowing. In particular, if the second encapsulation layer 542 included in the encapsulation layer 200 is an organic encapsulation layer made of an organic material, the dam DAM can prevent the overflow of the organic material.

Hereinafter, it will be described the structure or vertical structure of the display panel 110 according to the implementations of the present disclosure in more detail with reference to FIG. 5.

Referring to FIG. 5, a first buffer layer 511 may be disposed on a substrate 111. The first buffer layer 511 may be a single layer or a multilayer, but the implementations of the present disclosure are not limited thereto. If the first buffer layer 511 is a multilayer, the first buffer layer 511 may include a lower buffer layer 511a and an upper buffer layer 511b.

A first active layer ACT1 of a first thin film transistor TFT1 may be disposed on the first buffer layer 511. The first active layer ACT1 may include a channel area where a channel is formed, a source connection area on one side of the channel area, and a drain connection area on the other side of the channel area.

A first gate insulating layer 512 may be disposed on the first active layer ACT1 of the first thin film transistor TFT1. A first gate electrode E1a of the first thin film transistor TFT1 may be disposed on the first gate insulating layer 512. A first interlayer insulating layer 513 may be disposed on the first gate electrode E1a of the first thin film transistor TFT1. Here, a metal layer on which the first gate electrode E1a of the first thin film transistor TFT1 is disposed may be referred to as a first gate metal layer.

A second buffer layer 521 may be disposed on the first interlayer insulating layer 513.

The second active layer ACT2 of the second thin film transistor TFT2 may be disposed on the second buffer layer 521. The second active layer ACT2 may include a channel area in which a channel is formed, a source connection area on one side of the channel area, and a drain connection area on the other side of the channel area.

A second gate insulating layer 522 may be disposed on the second active layer ACT2 of the second thin film transistor TFT2. A second gate electrode E2a of the second thin film transistor TFT2 may be disposed. A second interlayer insulating layer 523 may be disposed on the second gate electrode E2a of the second thin film transistor TFT2. Here, the second gate electrode E2a of the second thin film transistor TFT2 may be referred to as a second gate metal layer.

The first source electrode E1b and the first drain electrode E1c of the first thin film transistor TFT1 and the second source electrode E2b and the second drain electrode E2c of the second thin film transistor TFT2 may be disposed on the second interlayer insulating layer 523.

The first source electrode E1b and the first drain electrode E1c of the first thin film transistor TFT1 may be connected to the source connection area and the drain connection area of the first active layer ACT1 through the holes of the second interlayer insulating layer 523, the second gate insulating layer 522, the second buffer layer 521, the first interlayer insulating layer 513, and the first gate insulating layer 512, respectively.

The second source electrode E2b and the second drain electrode E2c of the second thin film transistor TFT2 may be connected to the source connection area and the drain connection area of the second active layer ACT2 through the holes of the second interlayer insulating layer 523 and the second gate insulating layer 522, respectively.

The first source electrode E1b and the first drain electrode E1c of the first thin film transistor TFT1, and the second source electrode E2b and the second drain electrode E2c of the second thin film transistor TFT2 may include a first source-drain metal, and may be arranged within aa first source-drain metal layer.

Referring to FIG. 5, as an example, the storage capacitor Cst may be formed by the first capacitor electrode CAPE1 and the second capacitor electrode CAPE2. In some cases, the storage capacitor Cst may be formed by three or more capacitor electrodes, and may be in the form of two or more capacitors connected in parallel.

Each of the first capacitor electrode CAPE1 and the second capacitor electrode CAPE2 may be disposed on various metal layers disposed within the display panel 110.

For example, the first capacitor electrode CAPE1 may include the same first gate metal as the first gate electrode E1a of the first thin film transistor TFT1 on the first gate insulating layer 512, and may be disposed within a first gate metal layer, but the implementations of the present disclosure are not limited thereto. For example, the second capacitor electrode CAPE2 may be disposed on the first interlayer insulating layer 513.

The second source electrode E2b of the second thin film transistor TFT2 may be electrically connected to the second capacitor electrode CAPE2 through a hole of the second interlayer insulating layer 523, the second gate insulating layer 522, and the second buffer layer 521.

For example, if the sub-pixel SP is configured as in FIG. 2, the first thin film transistor TFT1 may be the scanning transistor ST of FIG. 2, and the second thin film transistor TFT2 may be the driving transistor DT of FIG. 2.

Referring to FIG. 5, the transistor section may further include a first shield pattern BSM1 disposed on the substrate 111. The first shield pattern BSM1 may overlap with the first active layer ACT1 of the first thin film transistor TFT1. The first shield pattern BSM1 may be disposed under the first active layer ACT1 of the first thin film transistor TFT1. For example, the first shield pattern BSM1 may be disposed between the substrate 111 and the first buffer layer 511, or may be disposed between the lower buffer layer 511a and the upper buffer layer 511b.

The transistor section may further include a second shield pattern BSM2 disposed on the substrate 111. The second shield pattern BSM2 may overlap with the second active layer ACT2 of the second thin film transistor TFT2. The second shield pattern BSM2 may be disposed under the second active layer ACT2 of the second thin film transistor TFT2. For example, the second shield pattern BSM2 may be disposed in a metal layer between the first interlayer insulating layer 513 and the second buffer layer 521. The second shield pattern BSM2 may be disposed in the same metal layer as the second capacitor CAPE2, but the implementations of the present disclosure are not limited thereto. For another example, the second shield pattern BSM2 may be disposed in the same first gate metal layer as the first gate electrode E1a of the first thin film transistor TFT1.

A planarization layer 530 may be disposed on the first thin film transistor TFT1 and the second thin film transistor TFT2, and may be disposed under the light emitting device ED. The planarization layer 530 may be an organic insulating layer including an organic insulating material.

As an example, the planarization layer 530 may be composed of one layer. As another example, the planarization layer 530 may include two layers. The planarization layer 530 may include a first planarization layer 531 and a second planarization layer 532. As another example, the planarization layer 530 may include three or more layers. The planarization layer 530 may include a first planarization layer 531, a second planarization layer 532, and a third planarization layer 533. The first planarization layer 531, the second planarization layer 532, and the third planarization layer 533 may be insulating layers. The implementations of the present disclosure are not limited thereto.

Referring to FIG. 5, the first planarization layer 531 may be disposed on the first source electrode E1b and the first drain electrode E1c of the first thin film transistor TFT1, and the second source electrode E2b and the second drain electrode E2c of the second thin film transistor TFT2. For example, the first planarization layer 531 may be disposed on the first thin film transistor TFT1 and the second thin film transistor TFT2. For example, the first planarization layer 531 may be disposed so as to cover both the first thin film transistor TFT1 and the second thin film transistor TFT2.

Referring to FIG. 5, a connection electrode RE may be disposed on the first planarization layer 531. The connection electrode RE may electrically connect the first source electrode E1b of the first thin film transistor TFT1 and the pixel electrode PE.

The connection electrode RE may be electrically connected to the first source electrode E1b of the first thin film transistor TFT1 through a hole of the first planarization layer 531.

The connection electrode RE may be disposed within the second source-drain metal layer on the first planarization layer 531, and may include a second source-drain metal.

The second planarization layer 532 may be disposed on the connection electrode RE.

Referring to FIG. 5, the light emitting device section may be disposed on the second planarization layer 532. The light emitting device ED may be formed on the second planarization layer 532. The light emitting device ED may include a pixel electrode PE, an intermediate layer EL, and a common electrode CE. The emission area EA of the light emitting device ED may be formed in an area where the pixel electrode PE, the intermediate layer EL, and the common electrode CE overlap and contact each other.

Referring to FIG. 5, the third planarization layer 533 may be disposed between the second planarization layer 532 and the pixel electrode PE of the light emitting device section. The third planarization layer 533 may form an opening in an area where the light emitting device section is disposed. That is, the light emitting device section may be disposed in the opening of the third planarization layer 533.

The third planarization layer 533 may be disposed to include the same material as the second planarization layer 532. The material included in the third planarization layer 533 is not limited thereto.

At least a portion of the pixel electrode PE may be disposed on the second planarization layer 532 so as to overlap with the opening of the third planarization layer 533. The pixel electrode PE may be electrically connected to the connection electrode RE through a hole of the second planarization layer 532.

The pixel electrode PE may include a flat surface PE_F disposed flatly along an upper surface of the second planarization layer 532. In addition, the pixel electrode PE may include an inclined surface PE_S extending along the side surface of the third planarization layer 533 in the opening of the third planarization layer 533.

A bank 540 may be disposed on the pixel electrode PE. The bank 540 may be disposed to cover the inclined surface PE_S of the pixel electrode PE. A hole of the bank 540 may expose a portion of the pixel electrode PE to form an emission area EA. The hole of the bank 540 may overlap with a portion of the pixel electrode PE. In addition, the hole of the bank 540 may overlap with a flat surface PE_F of the pixel electrode PE.

The bank 540 according to the implementation of the present disclosure may be a transparent bank including a transparent material.

The intermediate layer EL of the light emitting device ED may be disposed on a portion of the pixel electrode PE and the bank 540. The common electrode CE may be disposed on the intermediate layer EL.

Light output from the light emitting device ED can be output to the outside of the display panel 110 by transmitting the components arranged on the light emitting device ED. The emission area EA may be formed by the light output from the light emitting device ED. In this case, the emission area EA corresponding to the flat surface PE_F of the pixel electrode PE may be a main emission area M-EA.

Meanwhile, some of the light output from the light emitting device ED may be output in the side direction and reflected on the inclined surface PE_S of the pixel electrode PE. The light reflected on the inclined surface PE_S of the pixel electrode PE may be output to the outside of the display panel 110 to form the emission area EA corresponding to the inclined surface PE_S of the pixel electrode PE. In this case, the emission area EA corresponding to the inclined surface PE_S of the pixel electrode PE may be referred to as a sub-emission area S-EA. The sub-emission area S-EA may be formed in a ring shape surrounding the main emission area M-EA, but is not limited thereto.

According to an implementation of the present disclosure, a display device 100 may include a sub-emission area S-EA by forming a pixel electrode PE including an inclined surface PE_S, thereby providing an effect of increasing the brightness output from the display panel 110.

Referring to FIG. 5, an encapsulation section may be disposed on a light emitting device section, and may be located on a common electrode CE. The encapsulation section may include an encapsulation layer 200 formed on the common electrode CE.

The encapsulation layer 200 may prevent moisture or oxygen from penetrating into the light emitting device ED. For example, the encapsulation layer 200 may prevent moisture or oxygen from penetrating into an organic material included in an intermediate layer EL of the light emitting device ED. The encapsulation layer 200 may be composed of a single layer or a multilayer, but the implementations of the present disclosure are not limited thereto.

For example, the encapsulation layer 200 may include a first encapsulation layer 541, a second encapsulation layer 542, and a third encapsulation layer 543, but the implementations of the present disclosure are not limited thereto. For example, the first encapsulation layer 541 and the third encapsulation layer 543 may include inorganic encapsulation layers, and the second encapsulation layer 542 may include an organic encapsulation layer, but the implementations of the present disclosure are not limited thereto.

The display panel 110 according to the implementations of the present disclosure may also include a built-in touch sensor. In this case, the display panel 110 according to the implementations of the present disclosure may include a touch sensor layer 210 disposed on the encapsulation layer 200 and having a touch sensor formed thereon.

Referring to FIG. 5, the touch sensor layer 210 may include a plurality of touch electrodes TE corresponding to the touch sensor, and may include at least one touch metal layer for forming the plurality of touch electrodes TE.

For example, the touch sensor layer 210 may include a first touch metal layer on which a plurality of first touch metals TM1 are disposed, and a second touch metal layer on which a plurality of second touch metals TM2 are disposed, in order to form the plurality of touch electrodes TE. In this case, the touch sensor layer 210 may further include a touch interlayer insulating layer 552 disposed between the first touch metal layer and the second touch metal layer.

For example, one of the first touch metal layer and the second touch metal layer may be a sensor metal layer, and the other may be a bridge metal layer.

As an example, the first touch metal layer may be a bridge metal layer, and the second touch metal layer may be a sensor metal layer. In this case, the plurality of second touch metals TM2 arranged in the second touch metal layer may be sensor metals forming a touch sensor, and the plurality of first touch metals TM1 arranged in the first touch metal layer may be bridge metals electrically connecting the plurality of second touch metals TM2, which are sensor metals. For example, two or more second touch metals TM2 and at least one first touch metal TM1 may form one first touch electrode TE1. In this case, the two or more second touch metals TM2 may be electrically connected by at least one first touch metal TM1.

As another example, the first touch metal layer may be a sensor metal layer, and the second touch metal layer may be a bridge metal layer. In this case, the plurality of first touch metals TM1 arranged in the first touch metal layer may be sensor metals forming a touch sensor, and the plurality of second touch metals TM2 arranged in the second touch metal layer may be bridge metals electrically connecting the plurality of first touch metals TM1, which are sensor metals.

Referring to FIG. 5, the touch sensor layer 210 may further include a touch buffer layer 551 disposed on the encapsulation layer 200. The touch buffer layer 551 may be disposed between the encapsulation layer 200 and the touch metal layer. For example, the first touch metal layer may be disposed on the touch buffer layer 551, and the touch interlayer insulating layer 552 may be disposed on the first touch metal layer.

Referring to FIG. 5, the touch sensor layer 210 may further include a touch protection layer 553 disposed while covering the touch metal layer. For example, the touch protection layer 553 may be disposed on the second touch metal layer.

For example, the touch buffer layer 551 may be an inorganic layer including an inorganic insulating material or an organic layer including an organic insulating material, the touch interlayer insulating layer 552 may be an inorganic layer including an inorganic insulating material or an organic layer including an organic insulating material, and the touch protection layer 553 may be an inorganic layer including an inorganic insulating material or an organic layer including an organic insulating material.

For example, at least one of the touch buffer layer 551 and the touch interlayer insulating layer 552 may be disposed to extend from the display area DA to the non-display area NDA. The touch protection layer 553 may be disposed to extend from the display area DA to the non-display area NDA.

The touch routing line TL may electrically connect the touch electrode TE and the touch pad TP. The touch routing line TL may be composed of the first touch metal TM1 and/or the second touch metal TM2.

For example, the touch routing line TL may be composed of the first touch metal TM1, the second touch metal TM2, or both the first touch metal TM1 and the second touch metal TM2. If one touch routing line TL is composed of both the first touch metal TM1 and the second touch metal TM2, then both of the first touch metal TM1 and the second touch metal TM2 constituting one touch routing line TL may be electrically connected through a hole of the touch interlayer insulating layer 552.

For example, one touch routing line TL may include a plurality of line sections, and each of the plurality of line sections may be a single line section or a dual line section. Here, a single line section may be a line section with one signal path, and a double line section may be a line section with two signal paths connected in parallel.

The touch routing line TL may be arranged along the inclined surface SLP_ENCAP of the encapsulation layer 200, and may extend past the top of the dam DAM to the touch pad TP.

The touch buffer layer 551 may have an opening through which at least a part of the touch pad TP is exposed. The touch routing line TL may be electrically connected to the touch pad TP through the opening of the touch buffer layer 551. The touch interlayer insulating layer 552 may be disposed on the touch routing line TL, and may be extended to the area where the touch pad TP is arranged. The touch protection layer 553 may be disposed only on the display area DA, or may be disposed to extend to the non-display area NDA and may be disposed on the top of the touch routing line TL. In some cases, the touch protection layer 553 may extend further to the upper portion of the touch pad TP.

In some implementations. each of the plurality of touch electrodes TE may be a mesh-type electrode having a plurality of open areas OA. In this case, each of the plurality of touch electrodes TE may be composed of at least one second touch metal TM2. However, the implementations of the present disclosure are not limited thereto.

For example, the plurality of touch electrodes TE may include a first touch electrode TE1 and a second touch electrode TE2. If the first touch metal layer is a bridge metal layer and the second touch metal layer is a sensor metal layer, two or more second touch metals TM2 forming the first touch electrode TE1 corresponding to the touch sensor may be electrically connected through at least one first touch metal TM1 that is a bridge metal. For example, two second touch metals TM2 spaced apart from each other may be electrically connected by the first touch metal TM1 to form one first touch electrode TE1.

Referring to FIG. 5, the plurality of first touch metals TM1 and the plurality of second touch metals TM2 may be arranged so as not to overlap with the light emitting device ED. The plurality of first touch metals TM1 and the plurality of second touch metals TM2 may overlap with the bank 540. Accordingly, the light-emitting efficiency of the light emitting device ED can be improved.

If the plurality of touch electrodes TE are mesh-type electrodes having a plurality of open areas OA, the touch metals TM1 and TM2 may form a mesh shape.

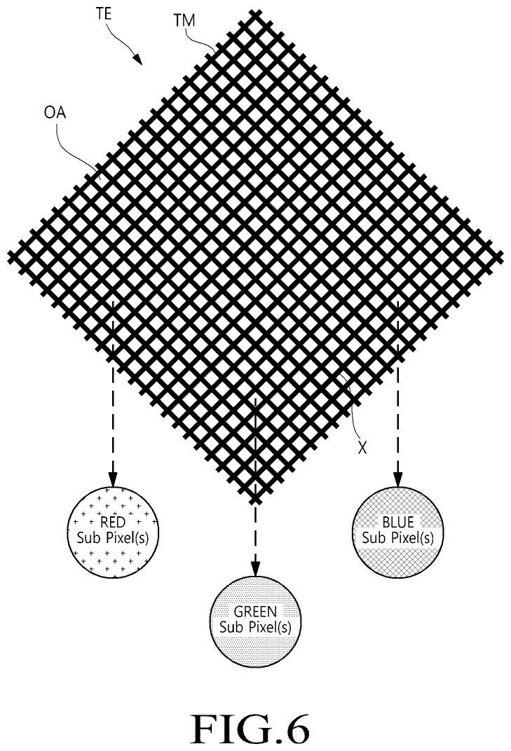

FIG. 6 is a drawing of an example of the correspondence between the mesh-type touch electrodes TE and the sub-pixels SP in the display device 100 according to some implementations of the present disclosure.

Referring to FIG. 6, each of the plurality of open areas OA existing in the area of the touch electrode TE including the touch metal TM patterned in the mesh-type may correspond to the emission area EA of one or more sub-pixels SP.

For example, each of the plurality of open areas OA existing within the area of one touch electrode TE may correspond to one or more emission areas EA among a red sub-pixel, a green sub-pixel, a blue sub-pixel, etc.

As another example, each of the plurality of open areas OA existing within the area of one touch electrode TE may correspond to one or more emission areas EA among a red sub-pixel, a green sub-pixel, a blue sub-pixel, and a white sub-pixel.

That is, each of the plurality of open areas OA existing within the area of the touch electrode TE may vertically overlap with the pixel electrode PE forming the emission area EA.

As described above, in a plan view, since the emission area EA of one or more sub-pixels SP exists in each of the open areas OA of each touch electrode TE, touch sensing is enabled, while also having the effect of further increasing the aperture ratio and light-emitting efficiency of the display panel 110.

As described above, the rough outline of the outer surface of one touch electrode TE may be a rhombus or a rectangle (including a square), and the open area OA corresponding to the hole in one touch electrode TE may also have a shape of a rhombus or a rectangle (including a square).

However, the shape of the touch electrode TE and the shape of the open area OA may be designed to be variously modified, considering the shape of the sub-pixel SP, the arrangement structure of the sub-pixels SP and the touch sensitivity.

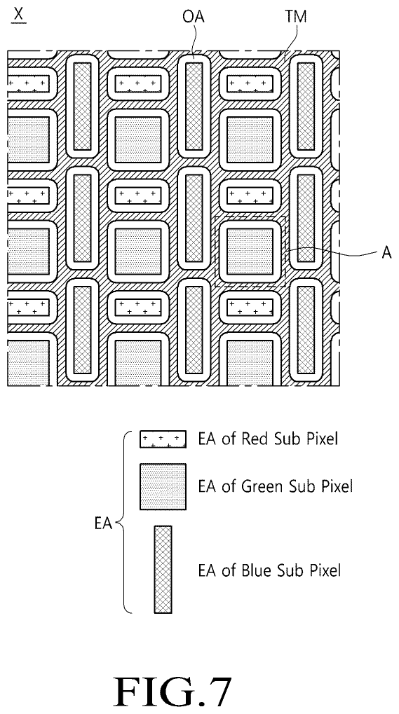

FIG. 7 is an example of a plan view that enlarges the X area of the touch electrode TE shown in FIG. 6.

Referring to FIG. 7, the open area OA may be formed according to the shape of each emission area EA corresponding to the sub-pixel SP.

Some open areas OA may correspond to the emission areas of red sub-pixels (EA of Red Sub-Pixel). Some open areas OA may correspond to the emission areas of green sub-pixels (EA of Green Sub-Pixel). Some open areas OA may correspond to the emission areas of blue sub-pixels (EA of Blue Sub-Pixel).

The touch metal TM may be formed in a mesh pattern so as not to overlap with each emission area EA.

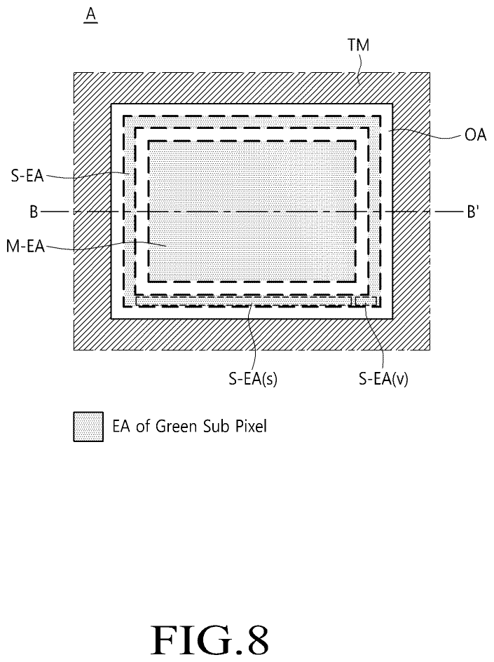

FIG. 8 is an example of a plan view that enlarges the A area of the touch electrode TE shown in FIG. 7.

Referring to FIG. 8, the touch metal TM included in the touch electrode TE may form an open area OA. An emission area EA may be disposed in the open area OA.

The emission area EA may include a main emission area M-EA and a sub-emission area S-EA.

Referring to FIG. 5 and FIG. 8, the main emission area M-EA may be an emission area EA that corresponds vertically to the flat surface PE_F of the pixel electrode PE.

Referring to FIG. 5 and FIG. 8, the sub-emission area S-EA may be an emission area EA that corresponds vertically to the inclined surface PE_S of the pixel electrode PE. In some implementations, the sub-emission area S-EA may be formed to surround the main emission area M-EA in a plan view.

In some implementations, the touch metal TM may be disposed to surround the sub-emission area S-EA in a plan view. The open area OA of the touch metal TM may overlap with the main emission area M-EA and the sub-emission area S-EA in the plan view.

The sub-emission area S-EA may include a corner sub-emission area S-EA(v) and a non-corner sub-emission area S-EA(s).

Referring to FIG. 8, the sub-emission area S-EA adjacent to each side of the main emission area M-EA may be a non-corner sub-emission area S-EA(s). In addition, the sub-emission area S-EA adjacent to the corners of the main emission area M-EA may be a corner sub-emission area S-EA(v).

Depending on the shape of the emission area EA, the amount of light reflected per unit area of the inclined surface PE_S of the pixel electrode PE corresponding to the corner sub-emission area S-EA(v) may be less than that of the inclined surface PE_S of the pixel electrode PE corresponding to the non-corner sub-emission area S-EA(s). Therefore, a problem can occur in which the brightness of light output from the corner sub-emission area S-EA(v) may be lower than the brightness of light output from the non-corner sub-emission area S-EA(s).

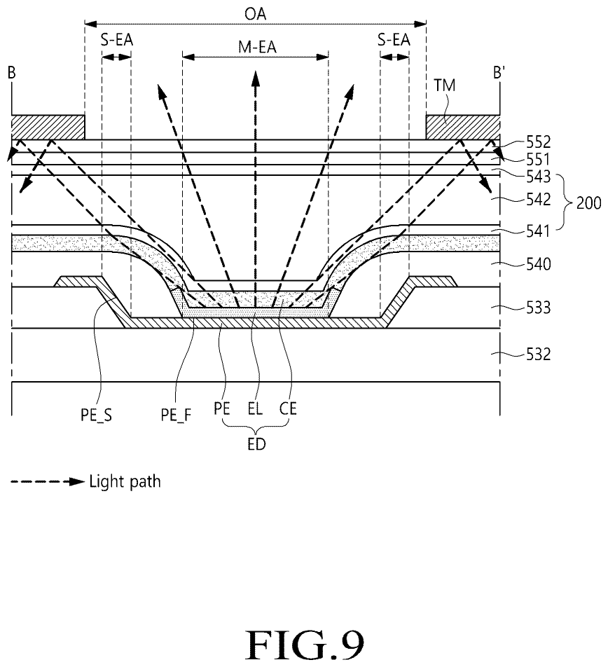

FIG. 9 is a part of a cross-sectional view of an example of the display panel 110 along the line B-B′ shown in FIG. 8.

As described above in FIG. 5, referring to FIG. 9, a third planarization layer 533 may be disposed on the second planarization layer 532. The third planarization layer 533 may form an opening in an area where a light emitting device ED is disposed. That is, the light emitting device ED may be disposed in the opening of the third planarization layer 533.

A pixel electrode PE may be disposed in the opening of the third planarization layer 533. The pixel electrode PE may be disposed to extend along a side of the opening of the third planarization layer 533 and include an inclined surface PE_S. For example, the pixel electrode PE may be disposed to include a flat surface PE_F corresponding to the opening of the third planarization layer 533 and an inclined surface PE_S corresponding to a side of the third planarization layer 533. In some implementations, the inclined surface PE_S of the pixel electrode PE may be disposed to surround the flat surface PE_F in a plan view.

A bank 540 may be disposed on the pixel electrode PE. The bank 540 may be disposed to include a hole overlapping a portion of the flat surface PE_F of the pixel electrode PE. The bank 540 may be disposed to cover an inclined surface of the pixel electrode PE.

An emission layer EL may be disposed in the hole of the bank 540. The emission layer EL may be disposed adjacent to the pixel electrode PE in the hole of the bank 540.

A common electrode CE may be disposed on the emission layer EL. The common electrode CE may extend along the side of the bank 540.

The pixel electrode PE, the emission layer EL, and the common electrode CE may overlap with each other to form a light emitting device ED. The area where the pixel electrode PE, the emission layer EL, and the common electrode CE overlap may form a main emission area M-EA. The main emission area M-EA may correspond to a part of the flat surface PE_F of the pixel electrode PE.

The inclined surface PE_S of the pixel electrode PE may emit light generated from the light emitting device ED to the outside of the display panel 110 to form a sub-emission area S-EA. The sub-emission area S-EA may correspond to the inclined surface PE_S of the pixel electrode PE on the plan view. In some implementations, the sub-emission area S-EA may be formed to surround the main emission area M-EA in a plan view.

An encapsulation layer 200 may be disposed on the common electrode CE. The encapsulation layer 200 may include a first encapsulation layer 541, a second encapsulation layer 542, and a third encapsulation layer 543.

A touch buffer layer 551 may be disposed on the encapsulation layer 200. A touch interlayer insulating layer 552 may be disposed on the touch buffer layer 551. A touch metal TM forming a touch electrode TE may be disposed on the touch interlayer insulating layer 552.

The touch metal TM may include an open area OA so that light output from the light emitting device ED may be output to the outside of the display panel 110. The touch metal TM may not be disposed in the open area OA. The light output from the light emitting device ED may be output to the outside of the display panel 110 through the open area OA of the touch metal TM.

The inclined surface PE_S of the pixel electrode PE may be disposed within the open area OA of the touch metal TM.

The touch metal TM may be disposed so as to overlap with the bank 540. The touch metal TM may be disposed so as not to overlap with the main emission area M-EA and the sub-emission area S-EA. Since the touch metal TM does not overlap with the main emission area M-EA and the sub-emission area S-EA, the light extraction efficiency may be increased, thereby increasing the brightness.

In some implementations, as shown in FIG. 9, some of the light output from the light emitting device ED may travel in an oblique direction and be reflected internally by the touch metal TM. The light reflected internally by the touch metal TM may not be output to the outside of the display panel 110, which may cause a problem of reduced light efficiency.

Accordingly, the display device 100 according to the implementations of the present disclosure may form one or more pores in the touch metal TM to transmit light output from the light emitting device ED to increase light efficiency.

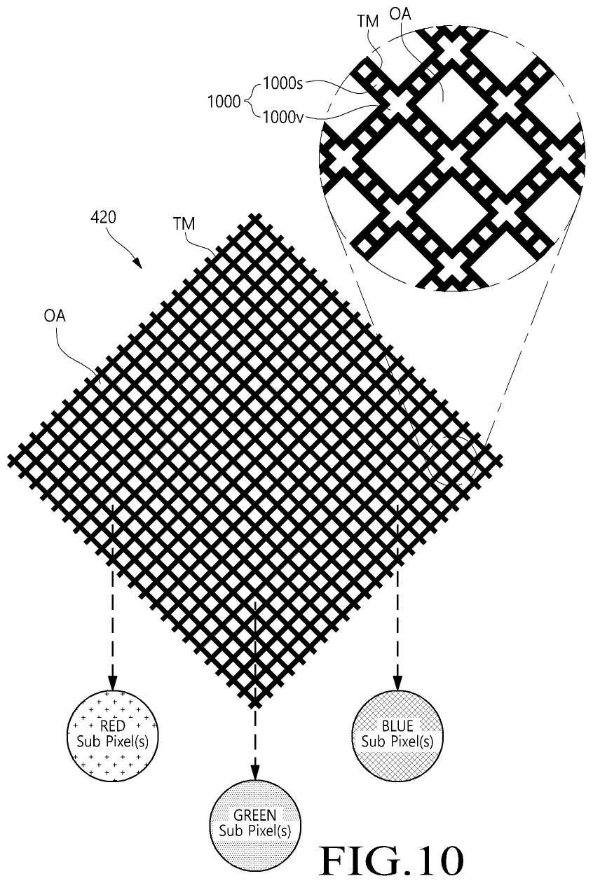

FIG. 10 is a drawing of an example of a mesh-type touch electrode TE including pores 1000 according to the implementations of the display device 100 of the present disclosure.

Referring to FIG. 10, the touch electrode TE may include a touch metal TM patterned in a mesh-type. Each of a plurality of open areas OA existing in the area of the touch electrode TE may correspond to an emission area EA of one or more sub-pixels SP.

For example, each of a plurality of open areas OA existing in the area of the touch electrode TE may vertically overlap with a pixel electrode PE forming an emission area EA.

In some implementations, the touch metal TM constituting the touch electrode TE may include a plurality of pores 1000. For example, the touch metal TM may be patterned in a mesh-type and may include a plurality of pores 1000 perforated in the touch metal TM in a direction perpendicular to the substrate 111. In some scenarios, the pores 1000 may include a corner pore 1000v and a non-corner pore 1000s.

The corner pore 1000v may be a pore 1000 adjacent to each vertex or corner of the open area OA of the touch electrode TE. The non-corner pore 1000s may be a pore 1000 adjacent to each side of the open area OA of the touch electrode TE. In some implementations, the size of the corner pore 1000v may be larger than the size of the non-corner pore 1000s.

In addition, each of the open areas OA of the touch electrode TE may be larger than the size of each of the plurality of pores 1000. That is, the open area OA may be larger than the non-corner pore 1000s. The open area OA may be larger than the corner pore 1000v.

In some implementations, the plurality of pores 1000 may be arranged to surround the open area OA along the touch metal TM of the touch electrode TE. As such, light from the sub-pixels SP can be emitted through the open areas OA as well as through the pores 1000, thus improving overall light extraction efficiency.

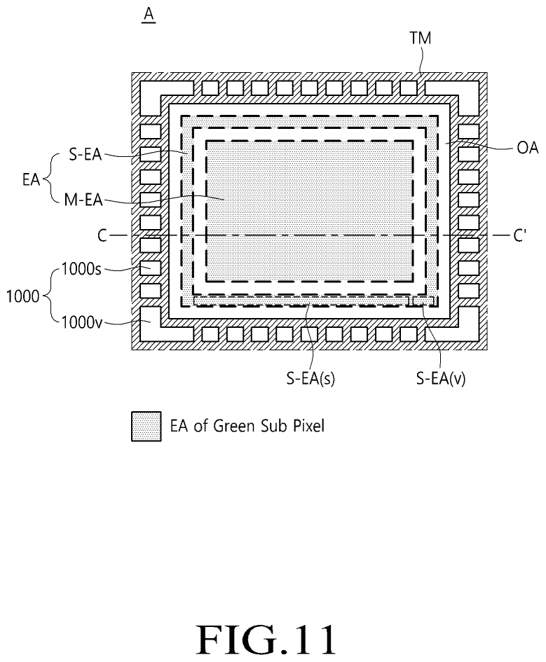

FIG. 11 is an example of a plan view of an enlarged area A of a touch electrode TE if the touch metal TM of the touch electrode TE in FIG. 7 includes pores 1000 as in FIG. 10.

Referring to FIG. 11, the touch metal TM included in the touch electrode TE may form an open area OA. An emission area EA may be disposed in the open area OA.

The emission area EA may include a main emission area M-EA and a sub-emission area S-EA.

Referring to FIG. 5 and FIG. 11, the main emission area M-EA may be an emission area EA that corresponds vertically to a flat surface PE_F of a pixel electrode PE.

Referring to FIG. 5 and FIG. 11, the sub-emission area S-EA may be an emission area EA that corresponds vertically to the inclined surface PE_S of the pixel electrode PE. The sub-emission area S-EA may be formed to surround the main emission area M-EA.

The touch metal TM may be disposed to surround the sub-emission area S-EA. The open area OA of the touch metal TM may overlap with the main emission area M-EA and the sub-emission area S-EA.

The sub-emission area S-EA may include a corner sub-emission area S-EA(v) and a non-corner sub-emission area S-EA(s).

As described above in FIG. 8, depending on the shape of the emission area EA, the amount of light reflected per unit area of the inclined surface PE_S of the pixel electrode PE corresponding to the corner sub-emission area S-EA(v) may be less than that of the inclined surface PE_S of the pixel electrode PE corresponding to the non-corner sub-emission area S-EA(s). Therefore, the luminance of light output from the corner sub-emission area S-EA(v) may be lower than the luminance of light output from the non-corner sub-emission area S-EA(s). Accordingly, a luminance unevenness problem may occur.

Meanwhile, the touch metal TM may include a pore 1000. The pore 1000 may include a corner pore 1000v and a non-corner pore 1000s. The corner pore 1000v may be larger than the non-corner pore 1000s.

The pore 1000 may provide a path for transmitting some of the light output from the light emitting device ED and outputting to the outside of the display panel 110. Therefore, light may be output from the touch metal TM area where the pore 1000 is formed.

In this case, since the size of the corner pore 1000v is larger than that of the non-corner pore 1000s, a larger amount of light may be output through the corner pore 1000v than the non-corner pore 1000s. Therefore, since more light is output through the corner pore 1000v than through the non-corner pore 1000s, the brightness in the area corresponding to the corner pore 1000v may be higher than the brightness in the area corresponding to the non-corner pore 1000s.

Referring to FIG. 11, the corner pore 1000v may be arranged adjacent to the corner sub-emission area S-EA(v), and the non-corner pore 1000s may be arranged adjacent to the non-corner sub-emission area S-EA(s). That is, the corner pore 1000v providing higher luminance than the non-corner pore 1000s may be arranged adjacent to the corner sub-emission area S-EA(v) having lower luminance than the non-corner sub-emission area S-EA(s). In addition, the non-corner pore 1000s providing lower luminance than the corner pore 1000v may be arranged adjacent to the non-corner sub-emission area S-EA(s) having higher luminance than the corner sub-emission area S-EA(v).

Accordingly, there may be an effect of compensating for the brightness unevenness problem due to the corner sub-emission area S-EA(v) having lower brightness than the non-corner sub-emission area S-EA(s).

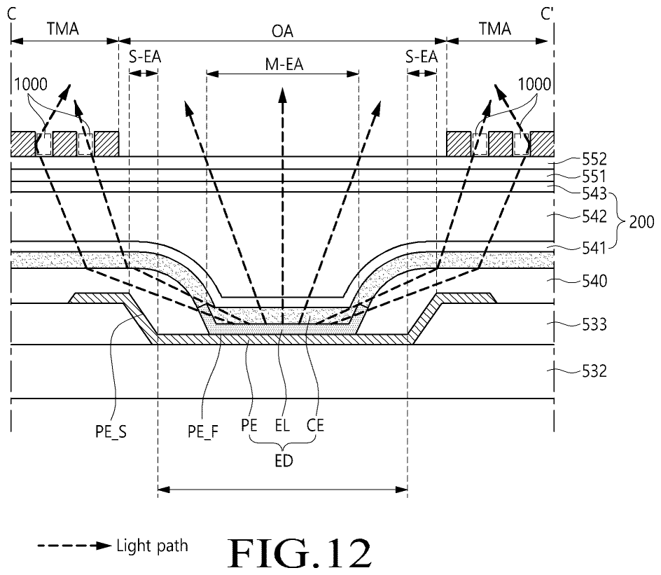

FIG. 12 is a part of a cross-sectional view of the display panel 110 shown along the line C-C′ shown in FIG. 11.

As described above in FIG. 5 and FIG. 9, referring to FIG. 11, a third planarization layer 533 may be disposed on the second planarization layer 532. The third planarization layer 533 may form an opening in an area where a light emitting device ED is disposed. That is, the light emitting device ED may be disposed in the opening of the third planarization layer 533.

A pixel electrode PE may be disposed in the opening of the third planarization layer 533. The pixel electrode PE may be disposed to extend along a side of the opening of the third planarization layer 533, and include an inclined surface PE_S. That is, the pixel electrode PE may be disposed to include a flat surface PE_F corresponding to the opening of the third planarization layer 533 and an inclined surface PE_S corresponding to the side surface of the third planarization layer 533. The inclined surface PE_S of the pixel electrode PE may be disposed to surround the flat surface PE_F.

A bank 540 may be disposed on the pixel electrode PE. The bank 540 may be disposed to include a hole overlapping with a portion of the flat surface PE_F of the pixel electrode PE. The bank 540 may be disposed to cover the inclined surface of the pixel electrode PE.

An emission layer EL may be disposed in the hole of the bank 540. The emission layer EL may be disposed adjacent to the pixel electrode PE in the hole of the bank 540. The hole of the bank 540 may have a smaller size than the opening of the second planarization layer 532.

A common electrode CE may be disposed on the emission layer EL. The common electrode CE may extend along the side of the bank.

The pixel electrode PE, the emission layer EL, and the common electrode CE may overlap with each other to form a light emitting device ED. The area where the pixel electrode PE, the emission layer EL, and the common electrode CE overlap may form a main emission area M-EA. The main emission area M-EA may correspond to a part of the flat surface PE_F of the pixel electrode PE.

The inclined surface PE_S of the pixel electrode PE may emit light generated from the light emitting device ED to the outside of the display panel 110 to form a sub-emission area S-EA. The sub-emission area S-EA may correspond to the inclined surface PE_S of the pixel electrode PE on the plan view. The sub-emission area S-EA may be formed to surround the main emission area M-EA.

An encapsulation layer 200 may be disposed on the common electrode CE. The encapsulation layer 200 may include a first encapsulation layer 541, a second encapsulation layer 542, and a third encapsulation layer 543.

A touch buffer layer 551 may be disposed on the encapsulation layer 200. A touch interlayer insulating layer 552 may be disposed on the touch buffer layer 551. A touch metal TM forming a touch electrode TE may be disposed on the touch interlayer insulating layer 552.

The touch metal TM may include an open area OA so as for the light output from the light emitting device ED to be output to the outside of the display panel 110. The touch metal TM may not be disposed in the open area OA. The light output from the light emitting device ED may be output to the outside of the display panel 110 through the open area OA of the touch metal TM.

The inclined surface PE_S of the pixel electrode PE may be disposed within the open area OA of the touch metal TM.

The touch metal TM may be disposed so as to overlap with the bank 540. The touch metal TM may be disposed so as not to overlap with the main emission area M-EA and the sub-emission area S-EA. Since the touch metal TM does not overlap with the main emission area M-EA and the sub-emission area S-EA, light extraction efficiency may be increased, thereby increasing the brightness.

In addition, a plurality of pores 1000 may be formed in the touch metal TM. The plurality of pores 1000 may be perforated in the touch metal TM in a vertical direction with the substrate 111. The plurality of pores 1000 may provide a path for transmitting some of the light output from the light emitting device ED to be output to the outside of the display panel 110. Accordingly, the touch metal area TMA with the plurality of pores 1000 may output light. In addition, the touch metal area TMA including the plurality of pores 1000 may be included in the emission area EA.

Referring to FIG. 12, some of the plurality of pores 1000 may vertically overlap with the pixel electrode PE. In addition, some of the remaining pores 1000 may not vertically overlap with the pixel electrode PE. In addition, the plurality of pores 1000 may overlap with the bank 540. The plurality of pores 1000 may not overlap with the emission layer EL.

Referring to FIG. 12, the display panel 110 may include a main emission area M-EA corresponding to the flat surface PE_F of the pixel electrode PE, a sub-emission area S-EA corresponding to the inclined surface PE_S of the pixel electrode PE, and a touch metal area TMA corresponding to the touch metal TM of the pixel electrode PE. In this case, in the touch metal area TMA, light may be output through the pore 1000.

The sub-emission area S-EA may be disposed to surround the main emission area M-EA. The touch metal area TMA may be disposed to surround the sub-emission area S-EA.

Meanwhile, the pore 1000 in the touch metal TM may be disposed in various shapes.

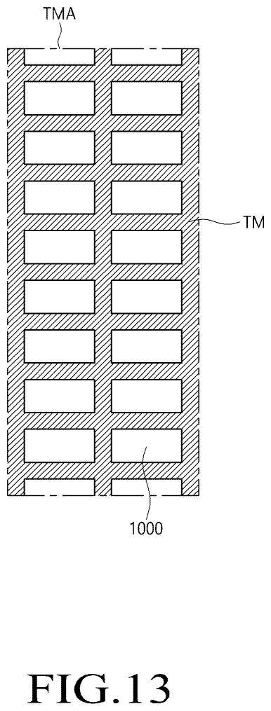

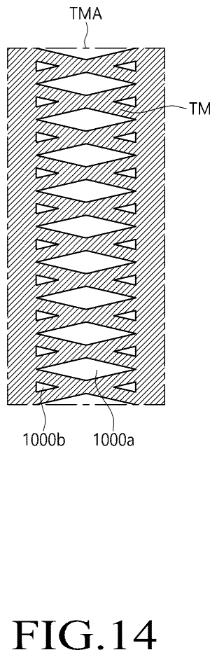

FIG. 13 and FIG. 14 are plan views illustrating examples of shapes of pores 1000 disposed in the touch metal TM.

For example, the plurality of pores 1000 disposed in the touch metal TM may all have the same shape. Referring to FIG. 13, the plurality of pores 1000 may all be squares of the same size.

The plurality of pores 1000 may be formed by patterning the touch metal TM in a ladder pattern.

As another example, the plurality of pores 1000 disposed in the touch metal TM may include pores 1000 of different shapes. Referring to FIG. 14, the plurality of pores 1000 disposed in the touch metal TM may include a first pore 1000 and a second pore 1000. The first pore 1000 and the second pore 1000 may have different shapes.

For example, the first pore 1000 may have a shape of a rhombus-shaped square. The second pore 1000 may have a shape of an isosceles triangle.

The first pore 1000 and the second pore 1000 may be alternately patterned and arranged on the touch metal TM at a ratio of 1:2.

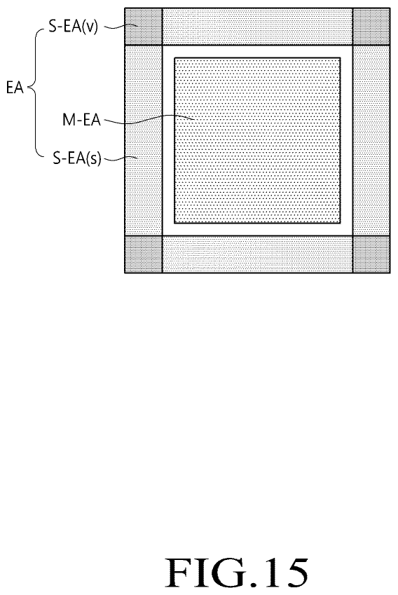

FIG. 15 illustrates an emission area EA in a plan view corresponding to FIG. 8.

Referring to FIG. 15, if the touch metal TM constituting the touch electrode TE does not include the pore 1000, the touch metal TM may include a main emission area M-EA and a sub-emission area S-EA.

The main emission area M-EA may be an emission area EA corresponding to the flat surface PE_F of the pixel electrode PE. The sub-emission area S-EA may be an emission area EA corresponding to the inclined surface PE_S of the pixel electrode PE.

Since the inclined surface PE_S of the pixel electrode PE is disposed to surround the flat surface PE_F of the pixel electrode PE, the sub-emission area S-EA may be disposed to surround the main emission area M-EA.

The sub-emission area S-EA may include a corner sub-emission area S-EA(v) and a non-corner sub-emission area S-EA(s).

In this case, as described above in FIG. 8 and FIG. 11, depending on the shape of the emission area EA, the brightness or the luminance of the corner sub-emission area S-EA(v) and the non-corner sub-emission area S-EA(s) may be different.

For example, the amount of light reflected per unit area of the inclined surface PE_S of the pixel electrode PE corresponding to the corner sub-emission area S-EA(v) may be less than that of the inclined surface PE_S of the pixel electrode PE corresponding to the non-corner sub-emission area S-EA(s). Therefore, the brightness of light output from the corner sub-emission area S-EA(v) may be darker or lower than the brightness of light output from the non-corner sub-emission area S-EA(s).

The size of the pore of the touch metal TM may be used to compensate for the dark brightness problem of the corner sub-emission area S-EA(v).

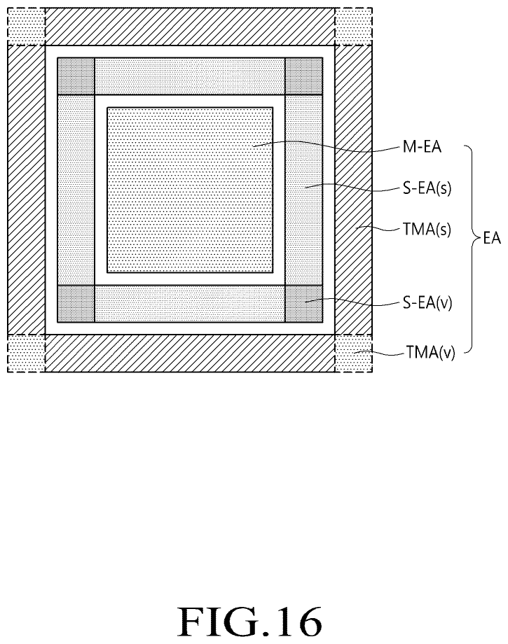

FIG. 16 illustrates an emission area EA in a plan view corresponding to FIG. 11.

Referring to FIG. 16, if the touch metal TM constituting the touch electrode TE includes a plurality of pores 1000, the touch metal TM may include a main emission area M-EA, a sub-emission area S-EA, and a touch metal area TMA.

Referring to FIGS. 11 and 16, the touch metal area TMA corresponding to an area where the touch metal TM is disposed may include a plurality of pores 1000 capable of outputting light to the outside of the display panel 110. Therefore, the touch metal area TMA may be included in the emission area EA.

The main emission area M-EA and the sub-emission area S-EA may be the same as the main emission area M-EA and the sub-emission area S-EA of FIG. 15 described above.

Referring to FIG. 16, the emission area EA of the display panel 110 may further include a touch metal area TMA. The touch metal area TMA may be disposed to surround the sub-emission area S-EA.

The touch metal area TMA may include a corner touch metal area EMA(v) and a non-corner touch metal area EMA(s).

Referring to FIG. 11 and FIG. 16, a corner pore 1000v may correspond to the corner touch metal area EMA(v). That is, the corner touch metal area EMA(v) and the corner pore 1000v may vertically overlap. In addition, a non-corner pore 1000s may correspond to the non-corner touch metal area EMA(s). That is, the non-corner touch metal area EMA(s) and the non-corner pore 1000s may be vertically overlapped.

In this case, the corner pore 1000v may have a larger size than the non-corner pore 1000s, and can output a larger amount of light. Therefore, the luminance of the corner touch metal area EMA(v) corresponding to the corner pore 1000v may be higher than the luminance of the non-corner touch metal area EMA(s) corresponding to the non-corner pore 1000s.

In addition, a corner touch metal area EMA(v) having a higher luminance than the non-corner touch metal area EMA(s) may be disposed adjacent to the corner sub-emission area S-EA(v) having a lower luminance than the non-corner sub-emission area S-EA(s). A non-corner touch metal area EMA(s) having lower luminance than the corner touch metal area EMA(v) may be adjacently disposed to a non-corner sub-emission area S-EA(s) having higher luminance than the corner sub-emission area S-EA(v).

A relatively dark corner sub-emission area S-EA(v) and a relatively bright corner touch metal area EMA(v) may be disposed adjacent to each other, so that there may provide an effect of reducing the problem of luminance non-uniformity in the emission area due to the lower brightness of the corner sub-emission area S-EA(v).

A display device according to implementations of the present disclosure may be briefly described as follows.

A display device according to implementations of the present disclosure may include a substrate including a display area and a non-display area, a plurality of pixel electrodes arranged on the display area of the substrate, a common electrode arranged on the plurality of pixel electrodes, an encapsulation layer disposed on the common electrode, and a touch electrode disposed on the encapsulation layer and including a touch metal having a plurality of open areas, wherein the touch metal is perforated with a plurality of pores that penetrate through the touch metal in a direction perpendicular to the substrate.

Each of the plurality of open areas may have a size larger than a size of each of the plurality of pores.

The plurality of open areas may vertically overlap with the plurality of pixel electrodes, respectively.

Each of the plurality of pores may not vertically overlap with at least a part of any of the plurality of pixel electrodes.

All of the plurality of pores may have the same shape.

At least one of the plurality of pores may have a different shape from the rest of the plurality of pores.

The display device according to implementations of the present disclosure may further include a first insulating layer disposed between the substrate and the plurality of pixel electrodes, a second insulating layer disposed on the first insulating layer and having an opening overlapping with a portion of a first pixel electrode among the plurality of pixel electrodes, a bank disposed on the first pixel electrode, overlapping with the opening and having a hole having a size smaller than the opening, and an emission layer disposed on the first pixel electrode. The common electrode may be disposed on the emission layer and extend along a side surface of the bank that defines the hole. The first pixel electrode may include a flat surface disposed on the first insulating layer and overlapping with the opening of the second insulating layer, and an inclined surface disposed on the first insulating layer in the opening and extending along a side surface of the second insulating layer that defines the opening.

The plurality of pores may overlap with the bank.

The plurality of pores may not overlap with the emission layer.

The inclined surface may be disposed within an open area among the plurality of open areas.

The display device according to implementations of the present disclosure may further include a first emission area overlapping with the flat surface, a second emission area overlapping with the inclined surface, and a third emission area outside the second emission area and overlapping with at least a part of the plurality of pores.

The second emission area may include a first corner area and a first non-corner area, and the first corner area may have a luminance lower than a luminance of the first non-corner area. The third emission area may include a second corner area and a second non-corner area, and the second corner area may have a luminance higher than a luminance of the second non-corner area.

The plurality of pores may include a first pore located in the second corner area, and a second pore located in the second non-corner area. Each of the first pores may have a size larger than each of the second pores.

A display device according to implementations of the present disclosure may include a substrate including a display area, a pixel electrode included in a sub-pixel disposed in the display area, the pixel electrode including a flat surface and an inclined surface outside a periphery of the flat surface, a bank disposed on the pixel electrode and having a hole overlapping with at least a portion of the pixel electrode, and a touch metal disposed on the bank and having a plurality of pores. An emission area of the sub-pixel may include a first emission area overlapping with the flat surface, a second emission area outside a periphery of the first emission area and overlapping with at least a portion of the inclined surface, and a third emission area outside a periphery of the second emission area and overlapping with at least a part of the plurality of pores.

The second emission area may include a first corner area and a first non-corner area, and the first corner area may have a luminance lower than a luminance of the first non-corner area.

The third emission area may include a second corner area and a second non-corner area, and the second corner area may have a luminance greater than a luminance of the second non-corner area.

The plurality of pores may include a first pore located in the second corner area, and a second pore located in the second non-corner area. Each of the first pores may have a size larger than each of the second pores.

The display device according to implementations of the present disclosure may further include a first insulating layer disposed between the substrate and the pixel electrode, a second insulating layer disposed on the first insulating layer and having an opening overlapping with a portion of the pixel electrode, an emission layer disposed on the pixel electrode, and a common electrode disposed on the emission layer and extending along a side surface of the bank that defines the hole. The pixel electrode may be disposed on the first insulating layer in the opening, and the inclined surface may extends along a side surface of the second insulating layer that defines the opening.

The above description has been presented to enable any person skilled in the art to make and use the technical idea of the present disclosure, and has been provided in the context of a particular application and its requirements. Various modifications, additions and substitutions to the described implementations will be readily apparent to those skilled in the art, and the general principles defined herein may be applied to other implementations and applications without departing from the spirit and scope of the present disclosure. The above description and the accompanying drawings provide an example of the technical idea of the present disclosure for illustrative purposes only. That is, the disclosed implementations are intended to illustrate the scope of the technical idea of the present disclosure.

What is claimed is:

1. A display device comprising:
a substrate including a display area and a non-display area;
a plurality of pixel electrodes arranged on the display area of the substrate;
a common electrode arranged on the plurality of pixel electrodes;
an encapsulation layer disposed on the common electrode; and
a touch electrode disposed on the encapsulation layer and including a touch metal having a plurality of open areas,
wherein the touch metal is perforated with a plurality of pores that penetrate through the touch metal in a direction perpendicular to the substrate.

2. The display device of claim 1, wherein each of the plurality of open areas has a size larger than a size of each of the plurality of pores.

3. The display device of claim 1, wherein the plurality of open areas vertically overlap with the plurality of pixel electrodes, respectively.

4. The display device of claim 1, wherein each of the plurality of pores does not vertically overlap with at least a part of any of the plurality of pixel electrodes.

5. The display device of claim 1, wherein all of the plurality of pores have a same shape.

6. The display device of claim 1, wherein at least one first pore among of the plurality of pores has a different shape from at least one second pore among the plurality of pores.

7. The display device of claim 1, further comprising:
a first insulating layer disposed between the substrate and the plurality of pixel electrodes;
a second insulating layer disposed on the first insulating layer and having an opening overlapping with a portion of a first pixel electrode among the plurality of pixel electrodes;
a bank disposed on the first pixel electrode, overlapping with the opening and having a hole having a size smaller than the opening; and
an emission layer disposed on the first pixel electrode,
wherein the common electrode is disposed on the emission layer and extends along a side surface of the bank that defines the hole,
wherein the first pixel electrode includes:
a flat surface disposed on the first insulating layer and overlapping with the opening of the second insulating layer, and
an inclined surface extending along a side surface of the second insulating layer that defines the opening.

8. The display device of claim 7, wherein the plurality of pores overlap with the bank.

9. The display device of claim 7, wherein the plurality of pores do not overlap with the emission layer.

10. The display device of claim 7, wherein the inclined surface of the first pixel electrode is disposed within an open area among the plurality of open areas.

11. The display device of claim 7, further comprising:
a first emission area overlapping with the flat surface of the first pixel electrode;
a second emission area overlapping with the inclined surface of the first pixel electrode; and
a third emission area outside the second emission area and overlapping with at least a part of the plurality of pores.

12. The display device of claim 11, wherein the second emission area includes a first corner area and a first non-corner area,
wherein the first corner area has a luminance lower than a luminance of the first non-corner area,
wherein the third emission area includes a second corner area and a second non-corner area,
wherein the second corner area has a luminance higher than a luminance of the second non-corner area.

13. The display device of claim 12, wherein the plurality of pores include:
a first pore located in the second corner area; and
a second pore located in the second non-corner area,
wherein the first pore has a size larger than the second pore.

14. A display device comprising:
a substrate including a display area;
a pixel electrode included in a sub-pixel disposed in the display area, the pixel electrode including a flat surface and an inclined surface outside a periphery of the flat surface;
a bank disposed on the pixel electrode and having a hole overlapping with at least a portion of the pixel electrode; and
a touch metal disposed on the bank and having a plurality of pores,
wherein an emission area of the sub-pixel includes:
a first emission area overlapping with the flat surface of the pixel electrode;
a second emission area outside a periphery of the first emission area and overlapping with at least a portion of the inclined surface of the pixel electrode; and
a third emission area outside a periphery of the second emission area and overlapping with at least a part of the plurality of pores.

15. The display device of claim 14, wherein the second emission area includes a first corner area and a first non-corner area,
wherein the first corner area has a luminance lower than a luminance of the first non-corner area.

16. The display device of claim 15, wherein the third emission area includes a second corner area and a second non-corner area,
wherein the second corner area has a luminance greater than a luminance of the second non-corner area.

17. The display device of claim 16, wherein the plurality of pores include:
a first pore located in the second corner area; and
a second pore located in the second non-corner area,
wherein the first pore has a size larger than the second pore.

18. The display device of claim 14, further comprising:
a first insulating layer disposed between the substrate and the pixel electrode;
a second insulating layer disposed on the first insulating layer and having an opening overlapping with a portion of the pixel electrode;
an emission layer disposed on the pixel electrode; and
a common electrode disposed on the emission layer and extending along a side surface of the bank that defines the hole,
wherein the pixel electrode is disposed on the first insulating layer in the opening, and the inclined surface of the pixel electrode extends along a side surface of the second insulating layer that defines the opening.

19. A display device comprising:
a substrate including a display area and a non-display area;
a plurality of pixel electrodes arranged on the display area of the substrate;
an encapsulation layer disposed on the plurality of pixel electrodes; and
a touch electrode disposed on the encapsulation layer,
wherein the touch electrode is arranged as a mesh shape in a plan view, the mesh shape including interconnected touch metal portions and a plurality of open areas defined between the interconnected touch metal portions, with the plurality of open areas corresponding to the plurality of pixel electrodes, and
wherein the interconnected touch metal portions are perforated with a plurality of pores disposed around each of the plurality of open areas.

20. The display device of claim 10, wherein each of the plurality of open areas has a size larger than a size of each of the plurality of pores.
